(19) United States
(12) Patent Application Publication
(10) Pub. No.: US 2026/0369233 A1
(43) Pub. Date: Nov. 19, 2026

(54) DISPLAY PANEL AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Xiyu ZHAO, Beijing (CN); Libin LIU, Beijing (CN); Yu FENG, Beijing (CN); Ling SHI, Beijing (CN); Jianbo XIAN, Beijing (CN)

(21) Appl. No.: 19/152,810

(22) PCT Filed: Jul. 31, 2024
(86) PCT No.: PCT/CN2024/108706

§ 371 Date: Jul. 31, 2025

(51) Int. Cl. G09G 3/3266; G09G 3/3233; H10K 59/131

(52) U.S. Cl. CPC G09G 3/3266; G09G 3/3233; H10K 59/131; G09G 2300/0426; G09G 2300/0819; G09G 2300/0842; G09G 2300/0861; G09G 2310/0286; G09G 2310/04; G09G 2320/0223; G09G 2320/0233; G09G 2330/021; G09G 2340/0435

(57) ABSTRACT

Provided are a display panel and a display device. The display panel includes a display area and a peripheral area around the display area; the display panel further includes: a plurality of sub-pixels, a gate driving circuit, and a power signal transmission layer, where the plurality of sub-pixels are located in the display area; the gate driving circuit comprises a plurality of shift register units, and the shift register units are coupled to corresponding sub-pixels; the power signal transmission layer comprises a portion located in the display area and a portion located in the peripheral area, and the shift register units are coupled to the power signal transmission layer.

### CROSS-REFERENCE TO RELATED APPLICATION

The present disclosure is the U.S. national phase of PCT Application PCT/CN2024/108706 filed on Jul. 31, 2024, the disclosure of which is incorporated in its entirety by reference herein.

### TECHNICAL FIELD

The present disclosure relates to the field of display technologies, particularly to a display panel and a display device.

### BACKGROUND

With the continuous development of display technologies, the application scope of display products has gradually expanded from small-to-medium-sized devices like smartwatches, mobile phones, and tablets to larger formats such as PCs and monitors. To achieve superior display performance, including reduced motion blur and enhanced screen response rate, a refresh rate of the display product has been gradually increased. However, the increased refresh rate concurrently elevates the power consumption of a processor and a chip of the whole device.

In specific usage scenarios, the display product often exhibits dynamic content changes only in a portion of a display area, such as a video playback or a gaming window, and the other region such as a comment region or an advertisement region is usually static and does not require a high refresh rate. To reduce power consumption, a local refresh functionality has been developed for display products, where a frequency of a scanning signal transmitted by a gate driving circuit to the display area by using a local refresh module, achieving partition refresh function. This allows different display areas in the display panel to achieve different refresh rates, thereby reducing power consumption of the display product.

### SUMMARY

The objective of the present disclosure is to provide a display panel and display device.

In order to achieve the above objective, the present disclosure provides the following technical solutions.

In a first aspect, the present disclosure provides a display panel, including: a display area and a peripheral area located around the display area. The display panel further includes:
a plurality of sub-pixels located in the display area;
a gate driving circuit including a plurality of shift register units, where the shift register units are coupled to the corresponding sub-pixels; and
a power signal transmission layer, where the power signal transmission layer includes a portion located in the display area and a portion located in the peripheral area, and the shift register units are coupled to the power signal transmission layer.

Optionally, the power signal transmission layer includes a power bus section and a power compensation section; the power bus section is located in the peripheral area, is coupled to the shift register units, and is further coupled to a power signal input terminal; and the power compensation section is coupled to the power bus section, and at least a portion of the power compensation section is located in the display area.

Optionally, the power compensation section includes a plurality of first power compensation lines, each of the first power compensation lines is coupled to the power bus portion, and at least a portion of the first power compensation lines is located in the display area.

Optionally, the power compensation section includes a plurality of second power compensation lines, an extension direction of the second power compensation line intersects with an extension direction of the first power compensation line, and the second power compensation lines are coupled to at least some of the first power compensation lines, respectively.

Optionally, the first power compensation line and the second power compensation line are arranged on a same layer.

Optionally, the first power compensation line and the second compensation line are arranged in different layers, and at least a portion of the first power compensation line is located between the second power compensation line and a base substrate of the display panel.

Optionally, the sub-pixels include a plurality of sub-pixel driving circuits, and the plurality of sub-pixel driving circuits included in the plurality of sub-pixels are divided into a plurality of rows of sub-pixel driving circuits; an orthographic projection of the first power compensation line onto a base substrate of the display panel overlaps at least partially with an orthographic projection of a corresponding row of sub-pixel driving circuits onto the base substrate; and there are n rows of sub-pixel driving circuits between two rows of sub-pixel driving circuits corresponding to two adjacent first power compensation lines, where n is greater than or equal to 0.

Optionally, the sub-pixel driving circuit includes a driving transistor, a local refresh control transistor, and a second reset transistor, a gate electrode of the driving transistor is coupled to a second electrode of the local refresh control transistor, and a second electrode of the driving transistor is coupled to a second electrode of the second reset transistor; the display panel further includes a second initialization signal line and a local refresh control line, the second initialization signal line is coupled to a first electrode of the second reset transistor included in each of sub-pixel driving circuits in a corresponding row of sub-pixel driving circuits; and the local refresh control line is coupled to a gate electrode of the local refresh control transistor included in each of sub-pixel driving circuits in a corresponding row of sub-pixel driving circuits; and at least a portion of the orthographic projection of the first power compensation line onto the base substrate is located between an orthographic projection of the second initialization signal line onto the base substrate and an orthographic projection of the local refresh control line onto the base substrate.

Optionally, the display panel further includes data lines, where the data line is coupled to each of sub-pixel driving circuits in a corresponding column of sub-pixel driving circuits; or, the display panel further includes a plurality of first data lines and a plurality of second data lines, the first data line is coupled to each of odd-numbered sub-pixel driving circuits in a corresponding column of sub-pixel driving circuits, the second data line is coupled to each of even-numbered sub-pixel driving circuits in a corresponding column of sub-pixel driving circuits; an orthographic projection of the first data line onto the base substrate is located on a first side of an orthographic projection of the column of sub-pixel driving circuits coupled to the first data line onto the base substrate, an orthographic projection of the second data line onto the base substrate is located on a second side of an orthographic projection of the column of sub-pixel driving circuits coupled to the second data line onto the base substrate, and the second side is opposite to the first side.

Optionally, the plurality of sub-pixel driving circuits included in the plurality of sub-pixels are divided into a plurality of columns of sub-pixel driving circuits; and orthographic projections of m columns of sub-pixel driving circuits onto a base substrate are located between orthographic projections of two adjacent second power compensation lines onto the base substrate, where m is greater than or equal to 1.

Optionally, the sub-pixel driving circuit includes a driving transistor and a compensation transistor, and a second electrode of the driving transistor is coupled to a first electrode of the compensation transistor; the display panel further includes data lines, and the data line is coupled to each of sub-pixel driving circuits in a corresponding column of sub-pixel driving circuits; and at least a portion of an orthographic projection of the second power compensation line onto the base substrate is located between an orthographic projection of an active layer of the compensation transistor onto the base substrate and an orthographic projection of a data line coupled to a sub-pixel driving circuit adjacent to the compensation transistor onto the base substrate.

Optionally, the sub-pixel driving circuit includes a driving transistor and a light emission control transistor, and a second electrode of the driving transistor is coupled to a first electrode of the light emission control transistor; the display panel further includes data lines, and the data line is coupled to each of sub-pixel driving circuits in a corresponding column of sub-pixel driving circuits; and at least a portion of an orthographic projection of the second power compensation line onto the base substrate is located between an orthographic projection of an active layer of the light emission control transistor onto the base substrate and an orthographic projection of a data line coupled to a sub-pixel driving circuit adjacent to the compensation transistor onto the base substrate.

Optionally, the display panel further includes a plurality of first data lines and a plurality of second data lines, where the first data line is coupled to each of odd-numbered sub-pixel driving circuits in a corresponding column of sub-pixel driving circuits, and the second data line is coupled to each of even-numbered sub-pixel driving circuits in a corresponding column of sub-pixel driving circuits; an orthographic projection of the first data line onto the base substrate is located on a first side of an orthographic projection of the column of sub-pixel driving circuits coupled to the first data line onto the base substrate, an orthographic projection of the second data line onto the base substrate is located on a second side of an orthographic projection of the column of sub-pixel driving circuits coupled to the second data line onto the base substrate, and the second side is opposite to the first side; and at least a portion of an orthographic projection of the second power compensation line onto the base substrate is located between orthographic projections of the first data line and the second data line that are adjacent to each other onto the base substrate.

Optionally, the display panel further includes a first power signal transmission layer and a second power signal transmission layer, where the first power compensation line included in the first power signal transmission layer and the first power compensation line included in the second power signal transmission layer are alternately arranged along a first direction.

Optionally, an orthographic projection of the first power compensation line included in the first power signal transmission layer onto the base substrate overlaps at least partially with an orthographic projection of an odd-numbered row of sub-pixel driving circuits onto the base substrate, and an orthographic projection of the first power compensation line included in the second power signal transmission layer onto the base substrate overlaps at least partially with an orthographic projection of an even-numbered row of sub-pixel driving circuits onto the base substrate; or, an orthographic projection of the first power compensation line included in the first power signal transmission layer onto the base substrate overlaps at least partially with an orthographic projection of an even-numbered row of sub-pixel driving circuits onto the base substrate, and an orthographic projection of the first power compensation line included in the second power signal transmission layer onto the base substrate overlaps at least partially with an orthographic projection of an odd-numbered row of sub-pixel driving circuits onto the base substrate.

Optionally, the second power compensation line included in the first power signal transmission layer and the second power compensation line included in the second power signal transmission layer are alternately arranged along a second direction, and the second direction intersects with the first direction.

Optionally, the sub-pixel driving circuit includes a first reset transistor, and a second electrode of the first reset transistor is coupled to a gate electrode of the driving transistor; the display panel further includes a first initialization signal transmission layer structure, the first initialization signal transmission layer structure includes a plurality of first initialization signal lines and a plurality of first initialization compensation lines; an extension direction of the first initialization compensation line intersects with an extension direction of the first initialization signal line; the first initialization signal line is coupled to a first electrode of the first reset transistor included in each of sub-pixel driving circuits in a corresponding row of sub-pixel driving circuits; and the first initialization compensation lines are coupled to at least some of the first initialization signal lines, respectively; and an orthographic projection of the first initialization compensation line onto the base substrate and an orthographic projection of the second power compensation line included in the first power signal transmission layer onto the base substrate are alternately arranged along the second direction; and/or, an orthographic projection of the first initialization compensation line onto the base substrate and an orthographic projection of the second power compensation line included in the second power signal transmission layer onto the base substrate are alternately arranged along the second direction.

Optionally, the sub-pixel driving circuit includes a second reset transistor, and a second electrode of the second reset transistor is coupled to a second electrode of the driving transistor; the display panel further includes a second initialization signal transmission layer structure, and the second initialization signal transmission layer structure includes a plurality of second initialization signal lines and a plurality of second initialization compensation lines, an extension direction of the second initialization compensation line intersects with an extension direction of the second initialization signal line; the second initialization signal line is coupled to a first electrode of the second reset transistor included in each of sub-pixel driving circuits in a corresponding row of sub-pixel driving circuits; and the second initialization compensation lines are coupled to at least some of the second initialization signal lines; and an orthographic projection of the second initialization compensation line onto the base substrate and an orthographic projection of the second power compensation line included in the first power signal transmission layer onto the base substrate are alternately arranged along the second direction; and/or, an orthographic projection of the second initialization compensation line onto the base substrate and an orthographic projection of the second power compensation line included in the second power signal transmission layer onto the base substrate are alternately arranged along the second direction.

Optionally, the sub-pixel driving circuit includes a third reset transistor, and a second electrode of the third reset transistor is coupled with a first electrode of the driving transistor; the display panel further includes a third initialization signal transmission layer structure, the third initialization signal transmission layer structure includes a plurality of third initialization signal lines and a plurality of third initialization compensation lines, an extension direction of the third initialization compensation line intersects with an extension direction of the third initialization signal line; the third initialization signal line is coupled to a first electrode of the third reset transistor included in each of sub-pixel driving circuits in a corresponding row of sub-pixel driving circuits; and the third initialization compensation line is coupled to at least some of the third initialization signal lines, respectively; and an orthographic projection of the third initialization compensation line onto the base substrate and the orthographic projection of the second power compensation line included in the first power signal transmission layer onto the base substrate are alternately arranged along the second direction; and/or, an orthographic projection of the third initialization compensation line onto the base substrate and the orthographic projection of the second power compensation line included in the second power signal transmission layer onto the base substrate are alternately arranged along the second direction.

Optionally, the sub-pixel driving circuit includes a first reset transistor, a second reset transistor, and a third reset transistor; a second electrode of the first reset transistor is coupled to a gate electrode of the driving transistor, a second electrode of the second reset transistor is coupled to a second electrode of the driving transistor, and a second electrode of the third reset transistor is coupled to the first electrode of the driving transistor;
the display panel further includes a first initialization signal transmission layer structure, a second initialization signal transmission layer structure, and a third initialization signal transmission layer structure;
the first initialization signal transmission layer structure includes a plurality of first initialization signal lines and a plurality of first initialization compensation lines; an extension direction of the first initialization compensation line intersects with an extension direction of the first initialization signal line; the first initialization signal line is coupled to a first electrode of the first reset transistor included in each of sub-pixel driving circuits in a corresponding row of sub-pixel driving circuits; and the first initialization compensation lines are coupled to at least some of the first initialization signal lines, respectively;
the second initialization signal transmission layer structure includes a plurality of second initialization signal lines and a plurality of second initialization compensation lines, an extension direction of the second initialization compensation line intersects with an extension direction of the second initialization signal line; the second initialization signal line is coupled to a first electrode of the second reset transistor included in each of sub-pixel driving circuits in a corresponding row of sub-pixel driving circuits; and the second initialization compensation lines are coupled to at least some of the second initialization signal lines, respectively;
the third initialization signal transmission layer structure includes a plurality of third initialization signal lines and a plurality of third initialization compensation lines, an extension direction of the third initialization compensation line intersects with an extension direction of the third initialization signal line; the third initialization signal line is coupled to a first electrode of the third reset transistor included in each of sub-pixel driving circuits in a corresponding row of sub-pixel driving circuits; and the third initialization compensation lines are coupled to at least some of the third initialization signal lines, respectively;
the second initialization compensation line, the third initialization compensation line, and the first initialization compensation line are sequentially arranged in a cyclical manner along the second direction; the second initialization compensation line, the third initialization compensation line, and the first initialization compensation line are arranged in a same layer and made of a same material; and
the second power compensation line included in the first power signal transmission layer and the second power compensation line included in the second power signal transmission layer are arranged in a same layer and made of a same material, and are arranged in the layer different from the first initialization compensation line.

Optionally, the display panel includes a first source drain metal layer, a first source drain metal layer, and a third source drain metal layer stacked in sequence along a direction away from the base substrate;
the first power compensation line included in the first power signal transmission layer and the first power compensation line included in the second power signal transmission layer are both arranged in a same layer and made of a same material as the first source drain metal layer;
the second power compensation line included in the first power signal transmission layer and the second power compensation line included in the second power signal transmission layer are both arranged in a same layer and made of a same material as the second source drain metal layer; and
the second initialization compensation line, the third initialization compensation line, and the first initialization compensation line are all arranged in a same layer and made of a same material as the third source drain metal layer.

Optionally, the sub-pixel driving circuit includes a first reset transistor, a second reset transistor, and a third reset transistor; a second electrode of the first reset transistor is coupled to a gate electrode of the driving transistor, a second electrode of the second reset transistor is coupled to a second electrode of the driving transistor, and a second electrode of the third reset transistor is coupled to a first electrode of the driving transistor;
the display panel further includes a first initialization signal transmission layer structure, a second initialization signal transmission layer structure, and a third initialization signal transmission layer structure;
the first initialization signal transmission layer structure includes a plurality of first initialization signal lines and a plurality of first initialization compensation lines; an extension direction of the first initialization compensation line intersects with an extension direction of the first initialization signal line; the first initialization signal line is coupled to a first electrode of the first reset transistor included in each of sub-pixel driving circuits in a corresponding row of sub-pixel driving circuits; and the first initialization compensation line is coupled to at least some of the first initialization signal lines, respectively;
the second initialization signal transmission layer structure includes a plurality of second initialization signal lines and a plurality of second initialization compensation lines, an extension direction of the second initialization compensation line intersects with an extension direction of the second initialization signal line; the second initialization signal line is coupled to a first electrode of the second reset transistor included in each of sub-pixel driving circuits in a corresponding row of sub-pixel driving circuits; and the second initialization compensation line is coupled to at least some of the second initialization signal lines, respectively;
the third initialization signal transmission layer structure includes a plurality of third initialization signal lines and a plurality of third initialization compensation lines, an extension direction of the third initialization compensation line intersects with an extension direction of the third initialization signal line; the third initialization signal line is coupled to a first electrode of the third reset transistor included in each of sub-pixel driving circuits in a corresponding row of sub-pixel driving circuits; and the third initialization compensation line is coupled to at least some of the third initialization signal lines, respectively;
the plurality of first initialization compensation lines, the plurality of second initialization compensation lines, the plurality of third initialization compensation lines, the plurality of second power compensation lines included in the first power signal transmission layer, and the plurality of second power compensation lines included in the second power signal transmission layer are divided into a plurality of first compensation groups, a plurality of second compensation groups, and a plurality of third compensation groups; the first compensation group, the second compensation group, and the third compensation group are sequentially arranged in a cyclical manner along the second direction;
the first compensation group includes the second initialization compensation line, the first initialization compensation line, and the third initialization compensation line arranged in sequence;
the second compensation group includes the second initialization compensation line, the first initialization compensation line, and the second power compensation line included in the first power signal transmission layer arranged in sequence; and
the second compensation group includes the second initialization compensation line, the first initialization compensation line, and the second power compensation line included in the second power signal transmission layer arranged in sequence.

Optionally, the display panel further includes a first source drain metal layer, a second source drain metal layer, and a third source drain metal layer stacked in sequence along a direction away from the base substrate;
the first power compensation line included in the first power signal transmission layer and the first power compensation line included in the second power signal transmission layer are both arranged in a same layer and made of a same material as the first source drain metal layer; and
the second power compensation line included in the first power signal transmission layer, the second power compensation line included in the second power signal transmission layer, the second initialization compensation line, the third initialization compensation line, and the first initialization compensation line are all arranged in a same layer and made of a same material as the third source drain metal layer.

Optionally, a line width d of the power bus section satisfies: 550 μm≤d≤150 μm.

Optionally, the power bus section includes a first bus layer, a second bus layer, and a third bus layer sequentially stacked along a direction away from a base substrate of the display panel, and the third bus layer is coupled to each of the first bus layer and the second bus layer.

Optionally, the display panel further includes a first gate metal layer, a second gate metal layer, and a first source drain metal layer sequentially stacked in a direction away from the base substrate; where the first bus layer is arranged in a same layer and made of a same material as the first gate metal layer, the second bus layer is arranged in a same layer and made of a same material as the second gate metal layer, and the third bus layer is arranged in a same layer and made of a same material as the first source drain metal layer.

Based on the above technical solutions of the display panel, in a second aspect, the present disclosure provides a display device, including the above display panel.

### BRIEF DESCRIPTION OF THE DRAWINGS

The accompanying drawings described herein are intended to provide further understanding of the present disclosure and form a part of the present disclosure. The illustrative embodiments and their descriptions of the present disclosure are used to explain the present disclosure and do not constitute undue limitations on the present disclosure. In the attached drawings:

FIG. 1 is a circuit schematic diagram of a sub-pixel driving circuit provided in an embodiment of the present disclosure;

FIG. 2 is a schematic cross-section view of a film layer of a display panel provided in an embodiment of the present disclosure;

FIG. 3 is a schematic diagram of a layout of a display area and a peripheral area of the display panel provided in an embodiment of the present disclosure;

FIG. 4 is a schematic diagram of a layout of a plurality of shift register units of a display panel provided in an embodiment of the present disclosure;

FIG. 5 is a schematic diagram of a first layout of some sub-pixels in the display panel provided in an embodiment of the present disclosure;

FIG. 6 is a schematic layout diagram of the sub-pixel driving circuits in FIG. 5;

FIG. 7 is a schematic layout diagram of a light shielding layer in FIG. 5;

FIG. 8 is a schematic layout diagram of a first active layer in FIG. 5;

FIG. 9 is a schematic layout diagram of a first gate metal layer in FIG. 5;

FIG. 10 is a schematic layout diagram of a second gate metal layer in FIG. 5;

FIG. 11 is a schematic layout diagram of a second active layer in FIG. 5;

FIG. 12 is a schematic layout diagram of a third gate metal layer in FIG. 5;

FIG. 13 is a schematic layout diagram of deep vias penetrating an intermediate insulation layer in FIG. 5;

FIG. 14 is a schematic layout diagram of trench vias penetrating an intermediate insulation layer in FIG. 5;

FIG. 15 is a schematic layout diagram of a first source drain metal layer in FIG. 5;

FIG. 16 is a schematic layout diagram of via holes included in a passivation layer and a first planarization layer in FIG. 5;

FIG. 17 is a schematic layout diagram of a second source drain metal layer in FIG. 5;

FIG. 18 is a schematic layout diagram of via holes included in a second planarization layer in FIG. 5;

FIG. 19 is a schematic layout diagram of a light shielding layer and a first active layer in FIG. 5;

FIG. 20 is a schematic layout diagram of a first active layer and a first gate metal layer in FIG. 5;

FIG. 21 is a schematic layout diagram of a first gate metal layer and a second gate metal layer in FIG. 5;

FIG. 22 is a schematic layout diagram of a second gate metal layer and a second active layer in FIG. 5;

FIG. 23 is a schematic layout diagram of a second active layer and a third gate metal layer in FIG. 5;

FIG. 24 is a schematic layout diagram of a third gate metal layer and deep vias and trench vias penetrating an intermediate insulation layer in FIG. 5;

FIG. 25 is a schematic layout diagram of a first source drain metal layer and deep vias and trench vias penetrating an intermediate insulation layer in FIG. 5;

FIG. 26 is a schematic layout diagram of a first source drain metal layer and a second source drain metal layer in FIG. 5;

FIG. 27 is a schematic layout diagram of a second source drain metal layer and a third source drain metal layer in FIG. 5;

FIG. 28 is a schematic layout diagram of via holes included in a third source drain metal layer and a third planarization layer in FIG. 5;

FIG. 29 is a schematic layout diagram of a third source drain metal layer and anode layer in FIG. 5;

FIG. 30 is a schematic diagram of a second layout of some sub-pixel driving circuits in the display panel provided in an embodiment of the present disclosure;

FIG. 31 is a schematic cross-section view taken along a horizontal dashed line in FIG. 30;

FIG. 32 is a schematic cross-section view taken along a vertical dashed line in FIG. 30;

FIG. 33 is a schematic diagram of a second layout of a power signal transmission layer in the display panel provided in an embodiment of the present disclosure;

FIG. 34 is an enlarged schematic diagram of the X1 part in FIG. 33;

FIG. 35 is a schematic layout diagram of a first source drain metal layer in sub-pixel driving circuits with two rows and three columns in the layout of FIG. 30;

FIG. 36 is a schematic layout diagram of via holes included in a passivation layer and a first planarization layer of sub-pixel driving circuits with two rows and three columns in the layout of FIG. 30;

FIG. 37 is a schematic layout diagram of a second source drain metal layer in sub-pixel driving circuits with two rows and three columns in the layout of FIG. 30;

FIG. 38 is a schematic layout diagram of the via holes included in a second planarization layer of sub-pixel driving circuits with two rows and three columns in the layout of FIG. 30;

FIG. 39 is a schematic layout diagram of a first source drain metal layer and a second source drain metal layer in sub-pixel driving circuits with two rows and three columns in the layout of FIG. 30;

FIG. 40 is a schematic layout diagram of a second source drain metal layer and a third source drain metal layer in sub-pixel driving circuits with two rows and three columns in the layout of FIG. 30;

FIG. 41 is a schematic layout diagram of the via holes included in a third source drain metal layer and a third planarization layer of sub-pixel driving circuits with two rows and three columns in the layout of FIG. 30;

FIG. 42 is a schematic diagram of a third layout of a power signal transmission layer in the display panel provided in an embodiment of the present disclosure;

FIG. 43 is an enlarged schematic diagram of the X2 part in FIG. 42;

FIG. 44 is a schematic cross-section view taken along a horizontal dashed line in FIG. 43;

FIG. 45 is a schematic cross-section view taken along a vertical dashed line in FIG. 43;

FIG. 46 is a schematic layout diagram of a first source drain metal layer in sub-pixel driving circuits with two rows and nine columns in the layout of FIG. 42;

FIG. 47 is a schematic layout diagram of via holes included in a passivation layer and a first planarization layer of sub-pixel driving circuits with two rows and nine columns in the layout of FIG. 42;

FIG. 48 is a schematic layout diagram of a second source drain metal layer in sub-pixel driving circuits with two rows and nine columns in the layout of FIG. 42;

FIG. 49 is a schematic layout diagram of the via holes included in a second planarization layer of sub-pixel driving circuits with two rows and nine columns in the layout of FIG. 42;

FIG. 50 is a schematic layout diagram of a first source drain metal layer and a second source drain metal layer of sub-pixel driving circuits with two rows and nine columns in the layout of FIG. 42;

FIG. 51 is a schematic layout diagram of a second source drain metal layer and a third source drain metal layer of sub-pixel driving circuits with two rows and nine columns in the layout of FIG. 42;

FIG. 52 is a schematic layout diagram of via holes included in a third source drain metal layer and a third planarization layer of sub-pixel driving circuits with two rows and nine columns in the layout of FIG. 42;

FIG. 53 is a schematic diagram of a fourth layout of the sub-pixel driving circuit in the display panel provided in an embodiment of the present disclosure;

FIG. 54 is a schematic layout diagram of a first source drain metal layer in sub-pixel driving circuits with two rows and three columns in the layout of FIG. 53;

FIG. 55 is a schematic layout diagram of via holes included in a passivation layer and a first planarization layer of sub-pixel driving circuits with two rows and three columns in the layout of FIG. 53;

FIG. 56 is a schematic layout diagram of a second source drain metal layer in sub-pixel driving circuits with two rows and three columns in the layout of FIG. 53;

FIG. 57 is a schematic layout diagram of a first source drain metal layer and a second source drain metal layer in sub-pixel driving circuits with two rows and three columns in the layout of FIG. 53;

FIG. 58 is a schematic layout diagram of a second source drain metal layer and a third source drain metal layer in sub-pixel driving circuits with two rows and three columns in the layout of FIG. 53;

FIG. 59 is a schematic diagram of a fifth layout of a power signal transmission layer in the display panel provided in an embodiment of the present disclosure;

FIG. 60 is an enlarged schematic diagram of the X3 part in FIG. 59;

FIG. 61 is a schematic layout diagram of a first source drain metal layer in sub-pixel driving circuits with two rows and nine columns in the layout of FIG. 59;

FIG. 62 is a schematic layout diagram of via holes included in a passivation layer and a first planarization layer of sub-pixel driving circuits with two rows and nine columns in the layout of FIG. 59;

FIG. 63 is a schematic layout diagram of a second source drain metal layer in sub-pixel driving circuits with two rows and nine columns in the layout of FIG. 59;

FIG. 64 is a schematic layout diagram of a first source drain metal layer and a second source drain metal layer in sub-pixel driving circuits with two rows and nine columns in the layout of FIG. 59;

FIG. 65 is a schematic layout diagram of a second source drain metal layer and a third source drain metal layer in sub-pixel driving circuits with two rows and nine columns in the layout of FIG. 59;

FIG. 66 is a schematic layout diagram of a power bus section on a side close to a power signal output terminal in the display panel provided in an embodiment of the present disclosure; and

FIG. 67 is an enlarged schematic diagram of the X4 section in FIG. 66.

### DETAILED DESCRIPTION

In order to further illustrate the display panel and the display device provided in embodiments of the present disclosure, a detailed description will be provided below in conjunction with the accompanying drawings of the specification.

When a display panel adopts a local refresh technology, a part of the display area is a high refresh rate area and the other part is a low refresh rate area. A gate driving circuit is affected by different refresh rates in different display areas, resulting in a load difference and causing a bright band problem in a boundary area, especially at a boundary position between the high refresh rate area and the low refresh rate area. Since a load in the high refresh rate area is greater than that in the low refresh rate area, a voltage of a power signal (such as VGH and VGL) connected to the gate driving circuit jumps, causing an increase in voltage jump when a local refresh control signal on the high-frequency side at the boundary, pulling down a gate voltage of the driving transistor in a sub-pixel drive circuit, resulting in the bright band at the boundary.

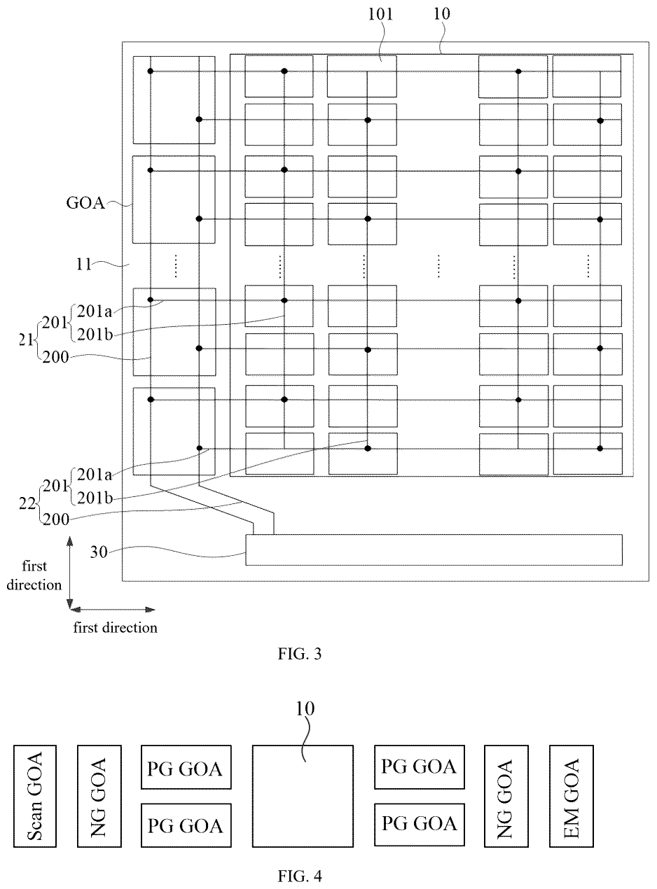

Referring to FIG. 3, an embodiment of the present disclosure provides a display panel, which includes: a display area 10 and a peripheral area 11 located around the display area 10. The display panel further includes:
a plurality of sub-pixels 101, where the plurality of sub-pixels 101 are located in the display area 10;
a gate driving circuit, where the gate driving circuit includes a plurality of shift register units GOA, and the shift register units GOA are coupled to corresponding sub-pixels 101;
a power signal transmission layer (such as a first power signal transmission layer 21 and a second power signal transmission layer 22), where the power signal transmission layer includes a portion located in the display area 10 and another portion located in the peripheral area 11, and the shift register units GOA are coupled to the power signal transmission layer.

For example, the display panel includes a display area 10 and a peripheral area 11, and the peripheral area 11 surrounds the display area 10, which are not limited thereto.

For example, the plurality of sub-pixels included by the display panel are located in the display area 10, and the plurality of sub-pixels are distributed in an array in the display area 10. The sub-pixel includes a sub-pixel driving circuit and a light-emitting element. The sub-pixel driving circuit is coupled to an anode of the light-emitting element, and is configured to provide a driving signal for the light-emitting element and to drive the light-emitting element to emit light.

For example, the gate driving circuit includes a plurality of shift register units cascaded, and the plurality of shift register units may be located in the peripheral area 11, or at least some of the shift register units are arranged in the display area 10 as needed. Each of the shift register units is coupled to a corresponding one of the sub-pixels, and is configured to provide a corresponding scanning signal for the corresponding sub-pixel.

It is worth noting that there are various types of sub-pixel driving circuits and gate driving circuits. An example is given that the sub-pixel driving circuit is of a 9T1C (including 9 transistors and 1 capacitor) circuit structure, a specific structure of the sub-pixel driving circuit and a specific type of the gate driving circuit will be explained below.

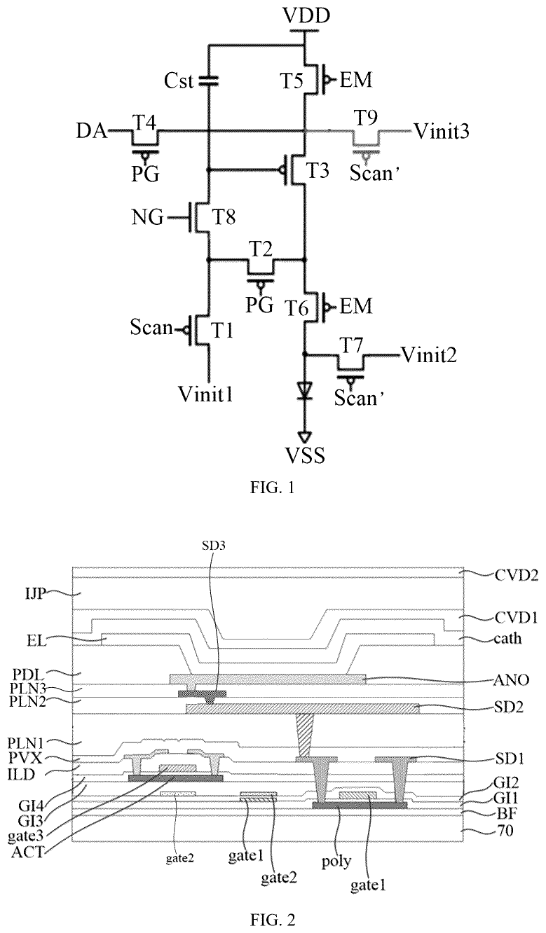

As shown in FIG. 1, the sub-pixel driving circuit includes a first transistor T1 to a ninth transistor T9 and a storage capacitor. The display panel includes: a power line VDD, a data line DA, a light emission control signal line EM, a first scanning line PG, a second scanning line NG, a third scanning line Scan, a first initialization signal transmission layer structure Vinit1, a second initialization signal transmission layer structure Vinit2, and a third initialization signal transmission layer structure Vinit3.

A gate electrode of the first transistor T1 is coupled to the corresponding third scanning line Scan, a first electrode of the first transistor T1 is coupled to the first initialization signal transmission layer structure Vinit1, a second electrode of the first transistor T1 is coupled to a first electrode of the eighth transistor T8, a gate electrode of the eighth transistor T8 is coupled to the corresponding second scanning line NG, and a second electrode of the eighth transistor T8 is coupled to a gate electrode T3-g of the third transistor T3.

A gate electrode of the second transistor T2 is coupled to the corresponding first scanning line PG, a first electrode of the second transistor T2 is coupled to a second electrode of the third transistor T3, and a second electrode of the second transistor T2 is coupled to the first electrode of the eighth transistor T8.

A gate electrode of the fourth transistor T4 is coupled to the corresponding first scanning line PG, a first electrode of the fourth transistor T4 is coupled to the corresponding data line DA, and a second electrode of the fourth transistor T4 is coupled to a first electrode of the third transistor T3.

A gate electrode of the fifth transistor T5 is coupled to the corresponding light emission control signal line EM, a first electrode of the fifth transistor T5 is coupled to the corresponding power line VDD, and a second electrode of the fifth transistor T5 is coupled to the first electrode of the third transistor T3.

A gate electrode of the sixth transistor T6 is coupled to the corresponding light emission control signal line EM, a first electrode of the sixth transistor T6 is coupled to the second electrode of the third transistor T3, a second electrode of the sixth transistor T6 is coupled to an anode of the light-emitting element, and a cathode of the light-emitting element is connected to a negative power signal VSS.

A gate electrode of the seventh transistor T7 is coupled to the corresponding third scanning line Scan′, a first electrode of the seventh transistor T7 is coupled to the second initialization signal transmission layer structure Vinit2, and a second electrode of the seventh transistor T7 is coupled to the anode of the light-emitting element.

A gate electrode of the ninth transistor T9 is coupled to the corresponding third scanning line Scan′, a first electrode of the ninth transistor T9 is coupled to the third initialization signal transmission layer structure Vinit3, and a second electrode of the ninth transistor T9 is coupled to the first electrode of the third transistor T3.

A first plate Cst of the storage capacitor Cst is coupled to a gate electrode of the third transistor T3, and a second plate Cst2 of the storage capacitor Cst is coupled to the power line VDD. For example, the first plate Cst of the storage capacitor Cst is reused as the gate electrode T3-g of the third transistor T3, which is not limited thereto.

For example, the third scanning line Scan′ coupled to the seventh transistor T7 and the ninth transistor T9 may be a third scanning line Scan coupled to a first transistor T1 in the next adjacent sub-pixel driving circuit along the first direction of the display panel, but is not limited to this.

As shown in FIG. 4, in a case that the above structure is adopted for the sub-pixel driving circuit, the gate driving circuit includes: a first gate scan driving circuit, a second gate scan driving circuit, a third gate scan driving circuit, and a light emission control gate driving circuit. The first gate scan driving circuit includes multiple cascaded first scan shift register units (PG GOA). The second gate scan driving circuit includes multiple cascaded second scan shift register units (NG GOA). The third gate scan driving circuit includes multiple cascaded third shift register units (Scan GOA). The light emission control gate driving circuit includes multiple cascaded light emission control shift register units (EM GOA).

As shown in FIG. 2, the display panel includes a buffer layer BF, a first active layer poly, a first gate insulation layer GI1, a first gate metal layer gatel, a second gate insulation layer GI2, a second gate metal layer gate2, a third gate insulation layer GI3, a second active layer ACT, a fourth gate insulation layer GI4, a third gate metal layer gate3, an intermediate insulation layer ILD, a first source drain metal layer SD1, a passivation layer PVX, a first planarization layer PLN1, a second source drain metal layer SD2, a second planarization layer PLN2, and a third source drain metal layer SD3, a third planarization layer PLN3, an anode layer ANO, a pixel defining layer PDL, a light emission functional layer EL, a cathode layer cath, a first inorganic encapsulation layer CVD1, an organic encapsulation layer IJP, and a second inorganic encapsulation layer CVD2, which are sequentially stacked in a direction away from a base substrate 70. As shown in FIG. 7, it is worth noting that the display panel further includes a light shielding layer LS.

For example, when controlling local refresh of the display panel, special control of NG GOA output is required, and special control of Scan GOA and EM GOA outputs are not required, that is, Scan GOA and EM GOA may maintain regular outputs, and PG GOA output may be optionally controlled, that is, PG GOA output may be specially controlled or PG GOA regular output may be maintained.

For example, the display panel includes at least one power signal transmission layer, the power signal transmission layer is coupled to each of the shift register units, and is configured to provide a corresponding power signal to the coupled shift register unit. For example, the power signal includes a DC power signal used in the shift register unit of the local refresh module. The local refresh module has been added to the shift register unit, enabling it to achieve local refresh of the display area 10.

For example, the power signal transmission layer includes a portion located in the display area 10 and a portion located in the peripheral area 11, where the portion located in the display area 10 is coupled to the portion located in the peripheral area 11.

According to the specific structure of the display panel described above, it may be seen that in the display panel provided in the embodiment of the present disclosure, the power signal transmission layer coupled to the shift register unit includes a portion located in the display area 10 and a portion located in the peripheral area 11, so that the power signal transmission layer can be laid out in both the display area 10 and the peripheral area 11 of the display panel. In this way, a larger layout space may be used inside the display panel, to enable the power signal transmission layer to have a smaller resistance value, which makes a power signal transmitted by the power signal transmission layer more stable, and effectively prevents a problem of a voltage jump of a power signal caused by a difference between loads of shift register units controlling different refresh rate areas, thereby avoiding a display difference between different refresh rate display areas 10. The display panel provided in the embodiment of the present disclosure adopts the above structure for the power signal transmission layer, which can prevent the problem of a bright band at the display boundary caused by a difference in loads between different refresh frequencies or refresh rates during local refreshing.

As shown in FIG. 3, in some embodiments, the power signal transmission layer includes: a power bus section 200 and a power compensation section 201; the power bus section 200 is located in the peripheral area 11. The power bus section 200 is coupled to the shift register units. The power bus section 200 is further coupled to a power signal input terminal 30; the power compensation section 201 is coupled to the power bus section 200, and at least a portion of the power compensation section 201 is located in the display area 10.

For example, the power bus section 200 is coupled to the power signal input terminal 30, and the power bus section 200 receives power signals from the power signal input terminal 30, and transmits the power signals to the power compensation section 201 and the shift register unit.

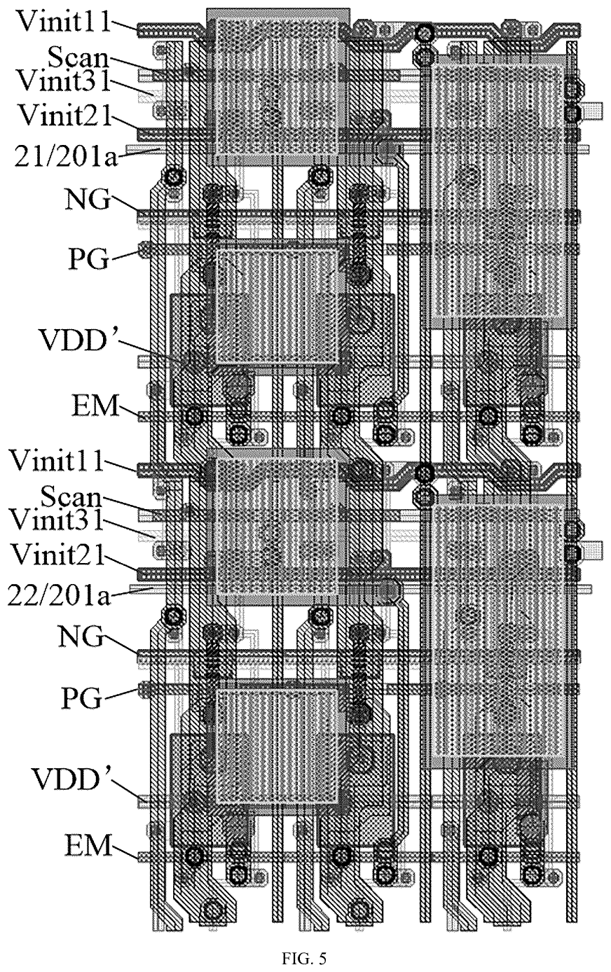

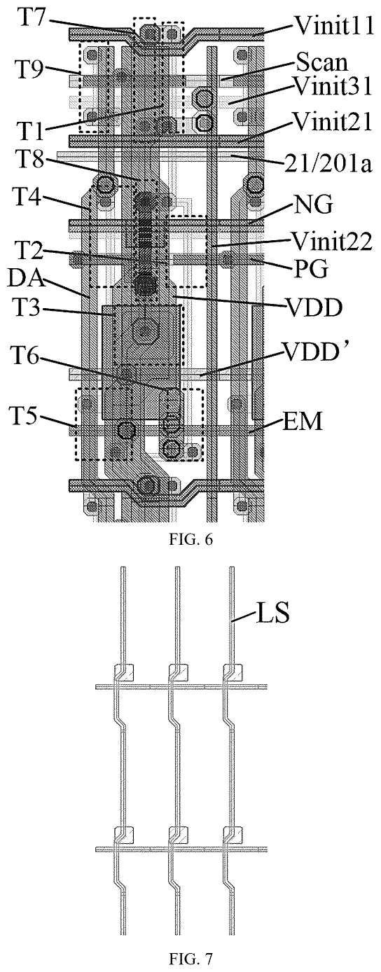

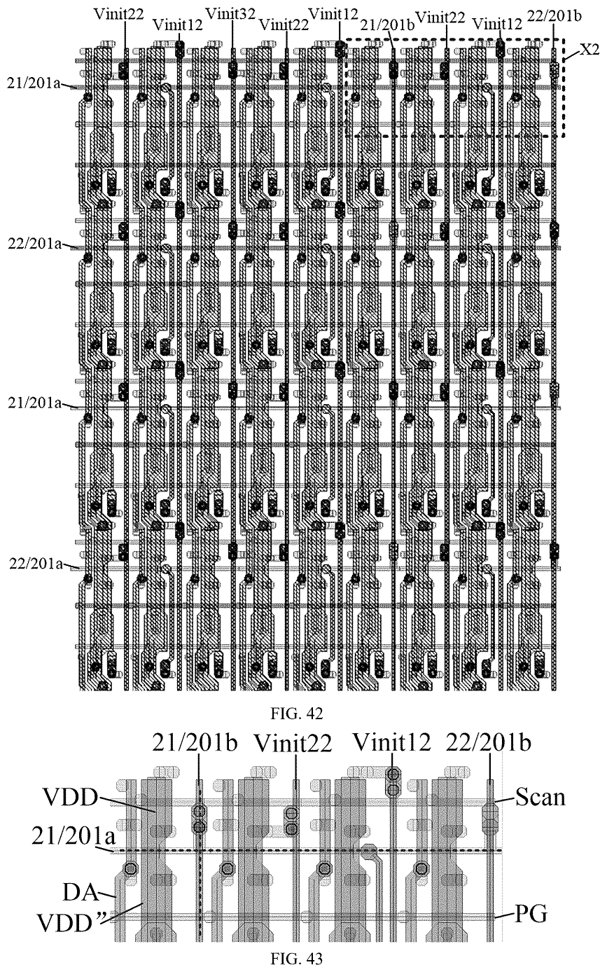

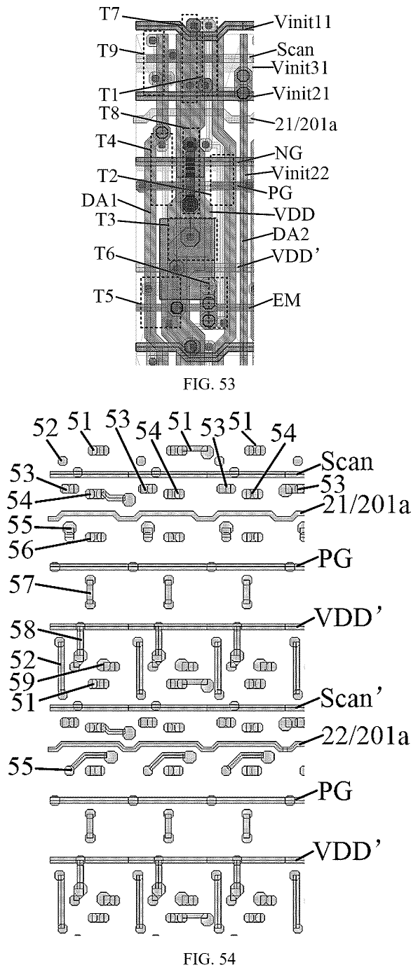

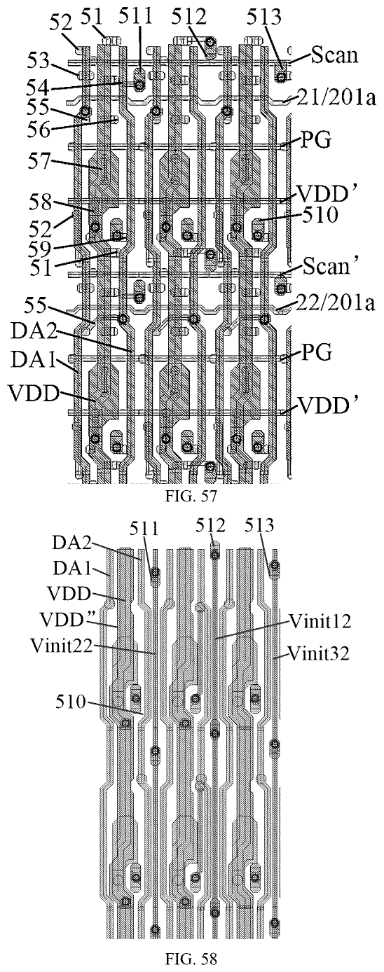

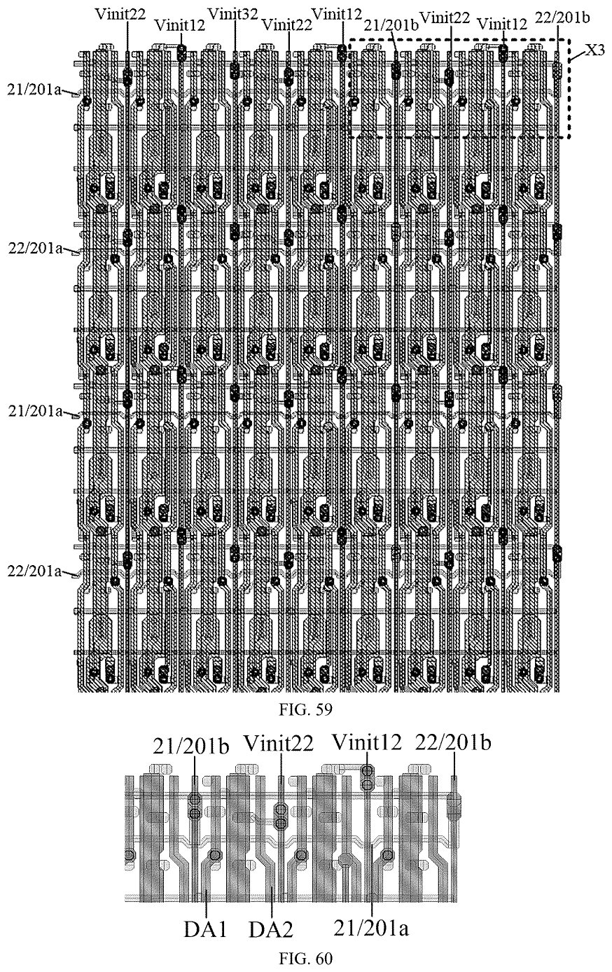

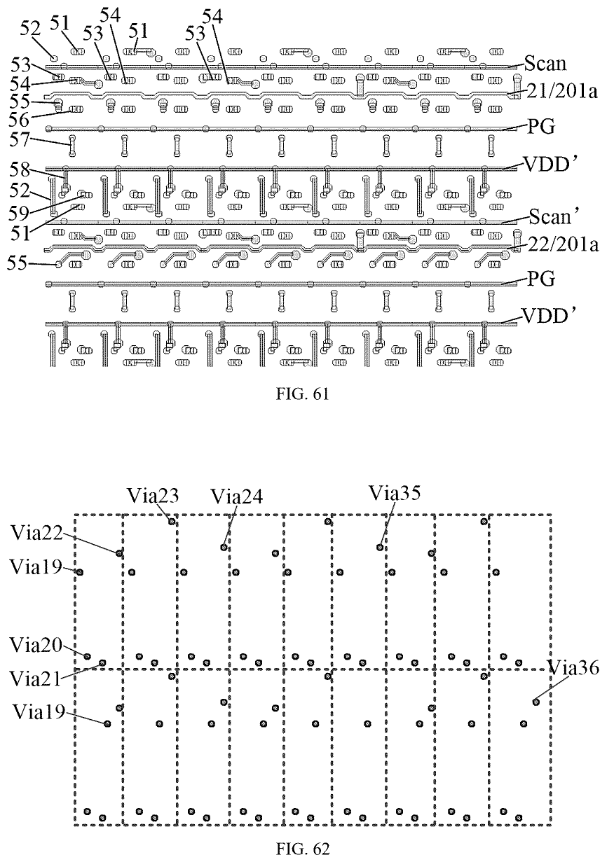

As shown in FIG. 3, FIG. 5, FIG. 6, FIG. 15, FIG. 30, FIG. 33, FIG. 35, FIG. 39, FIG. 42, FIG. 46, FIG. 53, FIG. 54, FIG. 57, FIG. 59 to FIG. 61, and FIG. 64, in some embodiments, the power compensation section 201 includes multiple first power compensation lines 201a, each of the multiple first power compensation lines 201a is coupled to the power bus section 200. At least a portion of the first power compensation line 201a is located in the display area 10.

As an example, the multiple first power compensation lines 201a are arranged along a first direction, and the first power compensation line 201a include at least a portion extending along a second direction. The second direction intersects the first direction. For example, the first direction includes the vertical direction, and the second direction includes the horizontal direction, but is not limited to these.

As an example, the first power compensation line 201a may extend from the peripheral area 11 to the display area 10. For example, the first power compensation line 201a may penetrate the display area 10, but is not limited to this.

In the above configuration, the power signal transmission layer can be laid out in both the display area 10 and the peripheral area 11 of the display panel, which enables the use of a larger layout space inside the display panel to achieve a power signal transmission layer with a smaller resistance value, thereby making a power signal transmitted by the power signal transmission layer more stable. It can effectively prevent the problem of a voltage jump in the power signal caused by the difference in loads of shift register units for controlling different refresh rate areas, thereby avoiding the display difference between display areas 10 of different refresh rates, and preventing the adverse problem of bright bands at a display boundary caused by the difference between the loads in different refresh rates during local flashing.

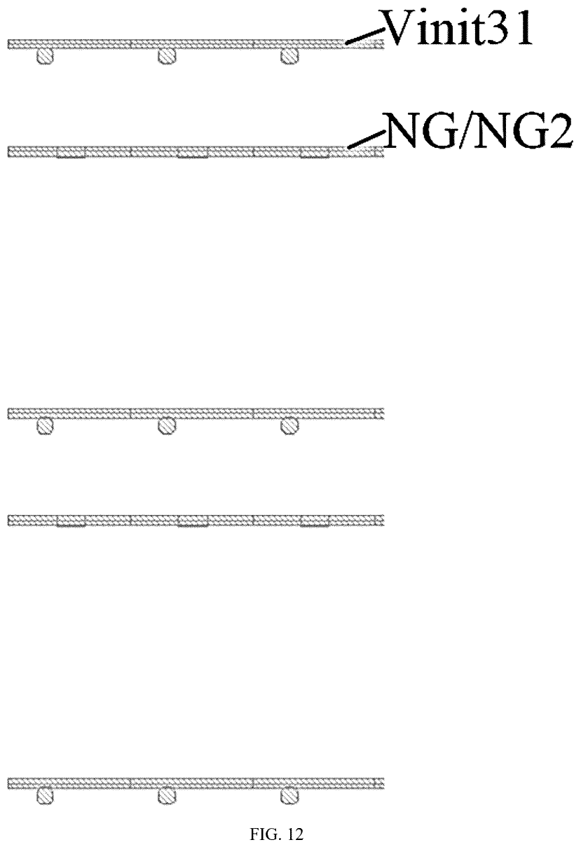

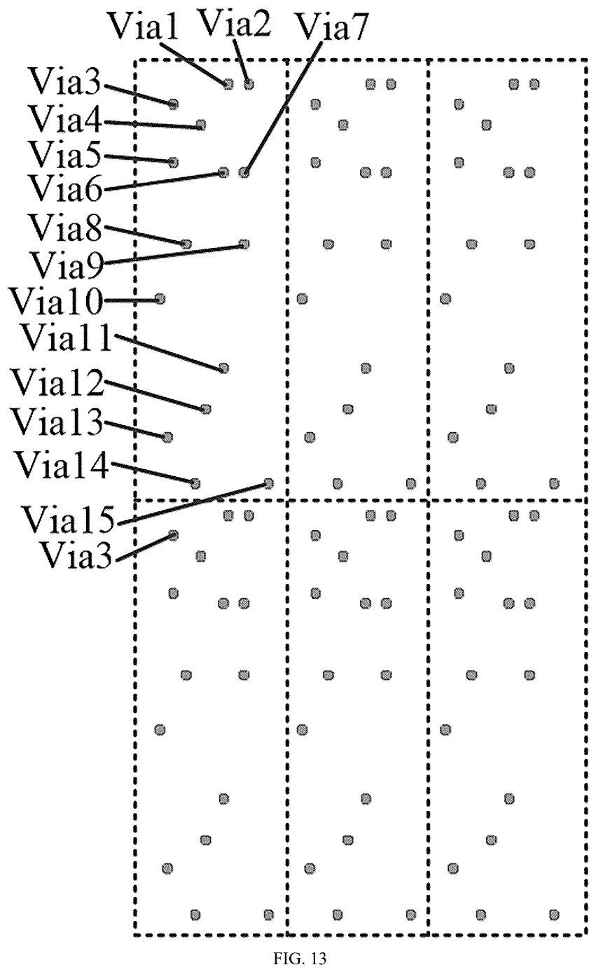

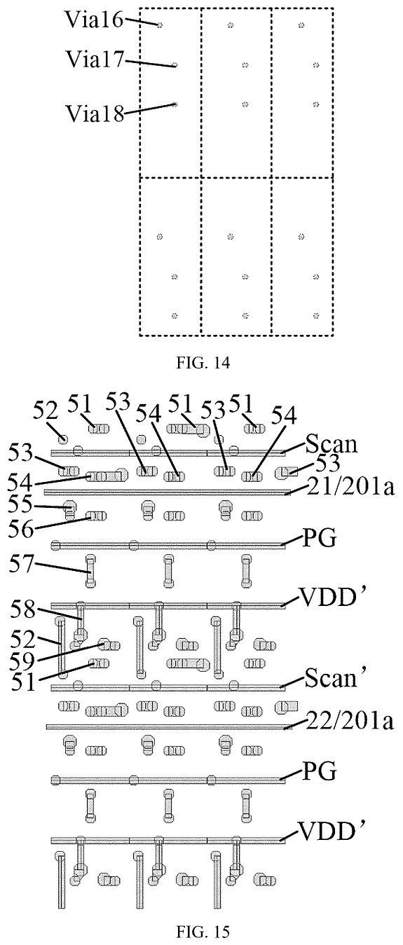

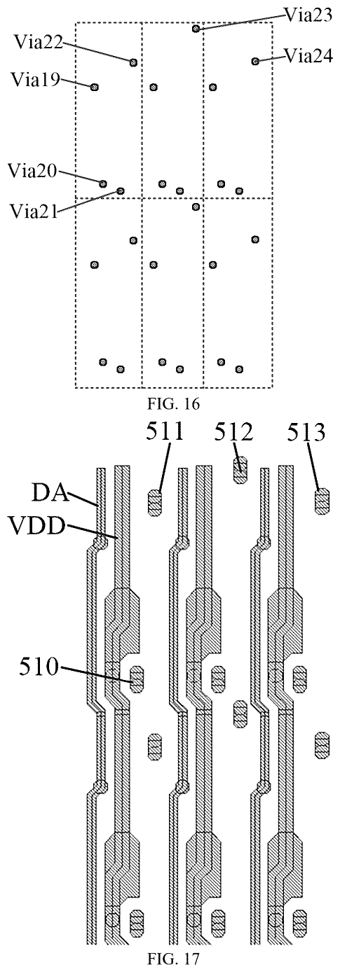

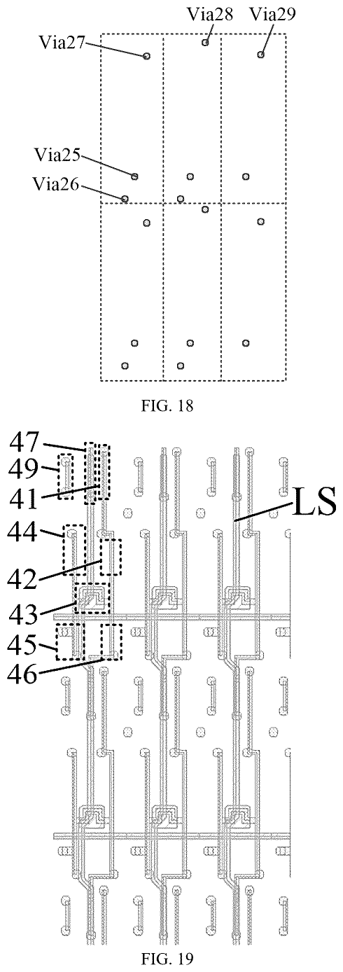

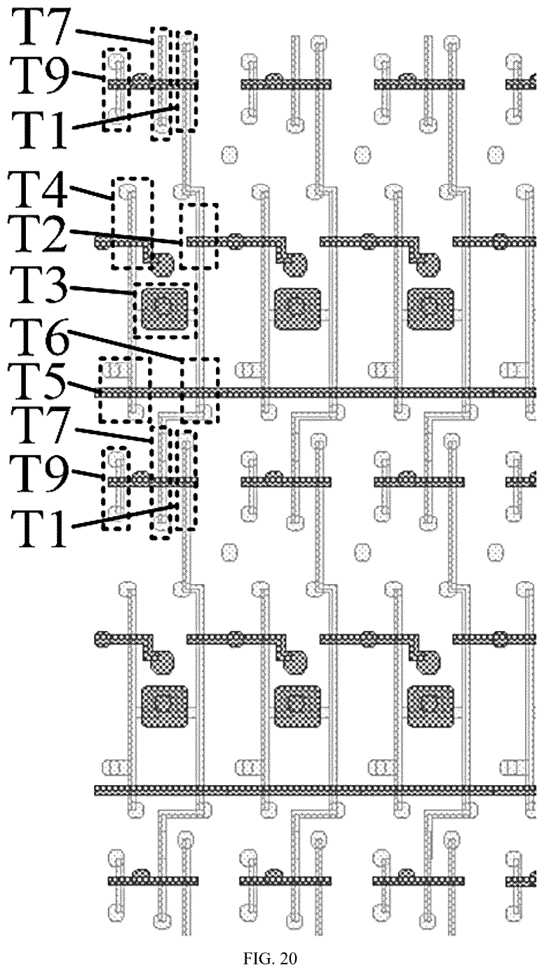

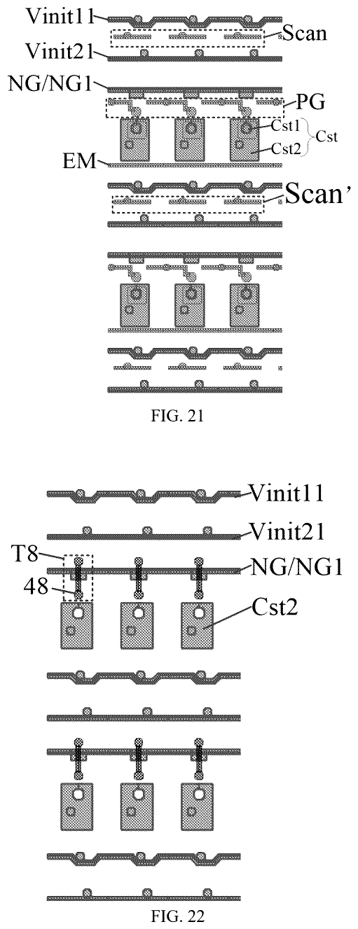

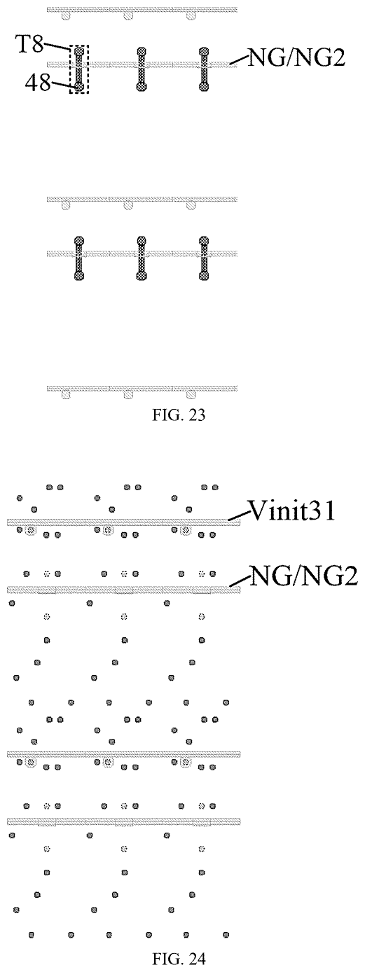

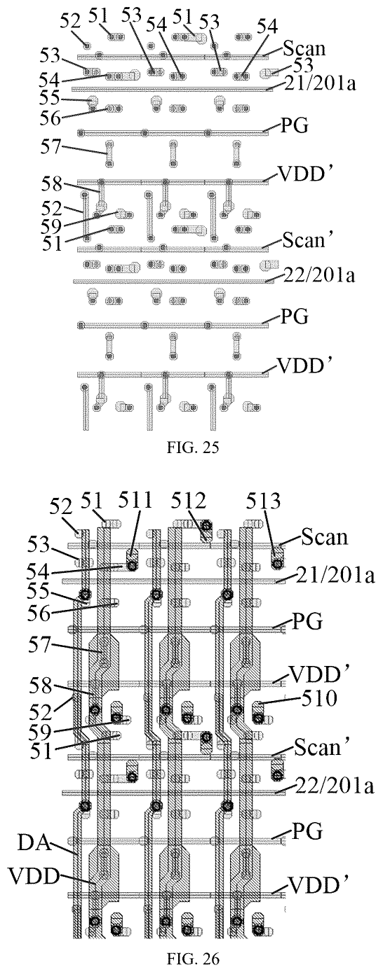

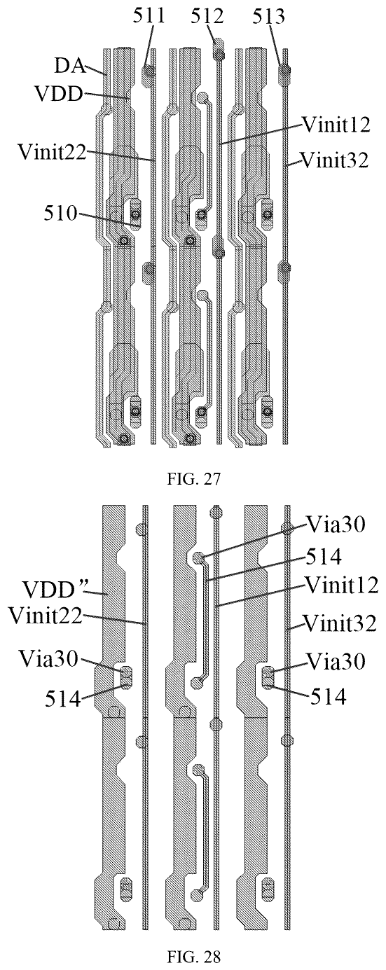

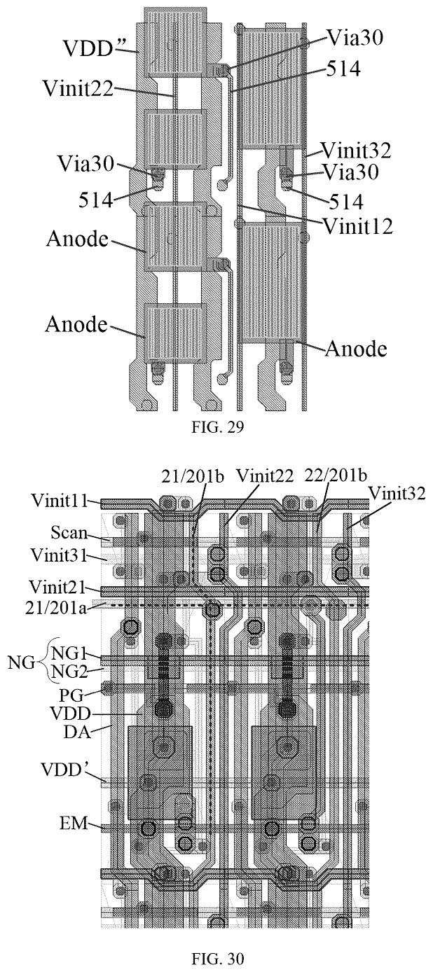

To be more specific, referring to FIG. 5 to FIG. 29, which illustrate the specific layout of the power compensation section 201 including multiple first power compensation lines 201a.

As shown in FIG. 7, the light shielding layer LS is illustrated.

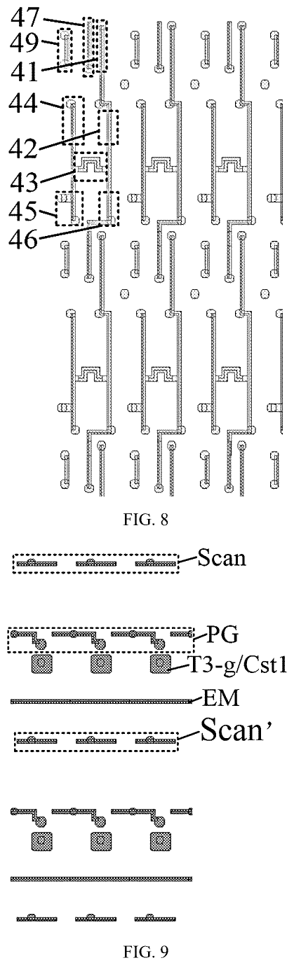

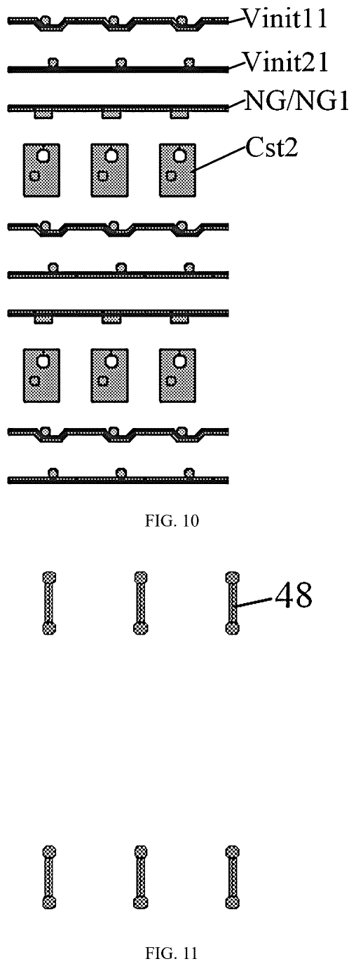

As shown in FIG. 8 and FIG. 11, the figures illustrate a first active pattern 41 included in the first transistor T1, a second active layer pattern 42 included in the second transistor T2, a third active layer pattern 43 included in the third transistor T3, a fourth active layer pattern 44 included in the fourth transistor T4, a fifth active layer pattern 45 included in the fifth transistor T5, a sixth active layer pattern 46 included in the sixth transistor T6, a seventh active layer pattern 47 included in the seventh transistor T7, an eighth active layer pattern 48 included in the eighth transistor T8, and a ninth active layer pattern 49 included in the ninth transistor T9. It should be noted that the eighth transistor T8 is an oxide transistor. As shown in FIG. 10 to FIG. 12 and FIG. 21 to FIG. 23, the second scan line NG connected to the gate electrode of the eighth transistor T8 includes a first scan layer NG1 and a second scan layer NG2.

As shown in FIG. 6 to FIG. 29, a first conductive connection part 51 is coupled to the first initialization signal line Vinit11 through a first via hole Via1, and the first conductive connection part 51 is coupled to the first electrode of the first transistor T1 through a second via hole Via2.

A second conductive connection part 52 is coupled to the second electrode of the ninth transistor T9 through the third via hole Via3, and to the second electrode of the fifth transistor T5 through a thirteenth via hole Via13.

The third scanning line Scan is coupled to the gate electrode of the first transistor T1, the gate electrode of the seventh transistor T7, and the gate electrode of the ninth transistor T9 through a fourth via hole Via4.

A third conductive connection part 53 is coupled to the first electrode of the ninth transistor T9 through a fifth via hole Via5, and is coupled to a third initialization signal line Vinit31 through a sixteenth via hole Via16.

A fourth conductive connection part 54 is coupled to the first electrode of the seventh transistor T7 through a sixth via hole Via6, and is coupled to a second initialization signal line Vinit21 through a seventh via hole Via7.

A fifth conductive connection part 55 is coupled to the first electrode of the fourth transistor T4 through an eighth via hole Via8, and is coupled to the data line DA through a nineteenth via hole Via19.

A sixth conductive connection part 56 is coupled to the first electrode of the eighth transistor T8 through a seventeenth via hole Via17, and is coupled to the second electrode of the second transistor T2 through a ninth via hole Via9.

A seventh conductive connection 57 is coupled to the second electrode of the eighth transistor T8 through an eighteenth via hole Via18, and is coupled to the gate electrode T3-g of the third transistor T3 through an eleventh via hole Via11.

The first scanning line PG is coupled to the gate electrode of the second transistor T2 and the gate electrode of the fourth transistor T4 through a tenth via hole Via10.

An eighth conductive connection part 58 is formed with the first compensation line VDD′ as a whole structure, and is coupled to the first electrode of the fifth transistor T5 through a fourteenth via hole Via14.

The first compensation line VDD′ is coupled to the second plate Cst2 of the storage capacitor Cst through a twelfth via hole Via12, the first compensation line VDD′ is coupled to the power line VDD through a twentieth via hole Via20, and the power line VDD is coupled to the second compensation line VDD′ through a twenty-sixth via hole Via26.

A ninth conductive connection part 59 is coupled to the second electrode of the sixth transistor T6 through a fifteenth via hole Via15, the ninth conductive connection part 59 is coupled to the tenth conductive connection part 510 through a twenty-first via hole Via21, a tenth conductive connection part 510 is coupled to the fourteenth conductive connection part 514 through a twenty-fifth via hole Via25, and a fourteenth conductive connection part 514 is coupled to an anode (Anode) pattern through a thirtieth via hole Via30.

In the embodiments illustrated in FIGS. 5 to 29, the power compensation section 201 in the power signal transmission layer only includes the first power compensation line 201a and does not include the second power compensation line 201b. In this case, the first initialization compensation line Vinit12, the second initialization compensation line Vinit22, and the third initialization compensation line Vinit32 may be laid out in the third source drain metal layer. In the embodiment, each column of sub-pixel driving circuits corresponds to one data line DA.

As shown in FIGS. 15 to 18 and FIGd. 25 to 28, in the layout area of the first column of sub-pixel driving circuits in the figure, the fourth conductive connection part 54 is coupled to the eleventh conductive connection part 511 through a twenty-second via hole Via22, and the eleventh conductive connection part 511 is coupled to the second initialization compensation line Vinit22 through a twenty-seventh via hole Via27.

In the layout area of the second column of sub-pixel driving circuits in the figure, the first conductive connection part 51 is coupled to a twelfth conductive connection part 512 through a twenty-third via hole Via23, and the twelfth conductive connection part 512 is coupled to the first initialization compensation line Vinit12 through a twenty-eighth via hole Via28.

In the layout area of the third column of sub-pixel driving circuits in the figure, the third conductive connection part 53 is coupled to a thirteenth conductive connection part 513 through a twenty-fourth via hole Via24, and the thirteenth conductive connection part 513 is coupled to the third initialization compensation line Vinit32 through a twenty-ninth via hole Via29.

It is worth noting that in the embodiments illustrated in FIGS. 5 to 29, the second initialization compensation line Vinit22, the first initialization compensation line Vinit12, and the third initialization compensation line Vinit32 are sequentially arranged in a cyclical manner along the second direction.

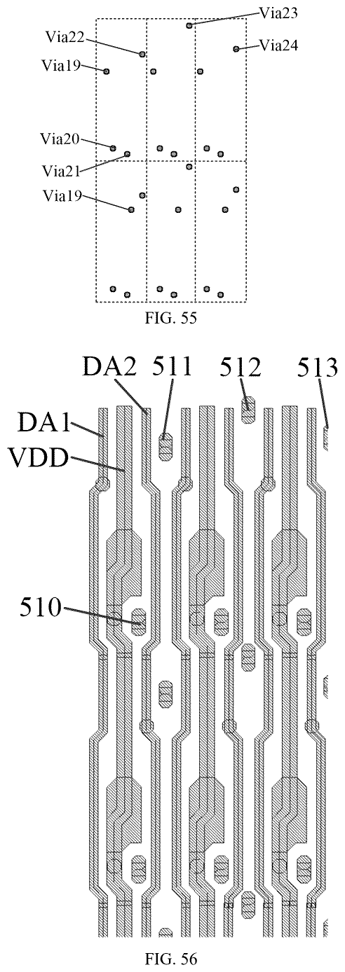

In the embodiments illustrated in FIGS. 53 to 58, the power compensation section 201 in the power signal transmission layer only includes the first power compensation line 201a and does not include the second power compensation line 201b. In this case, the first initialization compensation line Vinit12, the second initialization compensation line Vinit22, and the third initialization compensation line Vinit32 may be laid out in the third source drain metal layer. In the embodiment, each column of sub-pixel driving circuits corresponds to two data lines, such as the first data line DA1 and the second data line DA2.

It should be noted that the first initialization compensation line Vinit12 may be coupled with the first initialization signal line Vinit11 to form a grid like structure, which is beneficial for reducing a voltage drop generated when a first initialization signal is transmitted in the first initialization signal line Vinit11. The second initialization compensation line Vinit22 may be coupled with the second initialization signal line Vinit21 to form a grid like structure, which is beneficial for reducing a voltage drop generated when a second initialization signal is transmitted in the second initialization signal line Vinit21. The third initialization compensation line Vinit32 may be coupled with the third initialization signal line Vinit31 to form a grid like structure, which is beneficial for reducing a voltage drop generated when a third initialization signal is transmitted in the third initialization compensation line Vinit32.

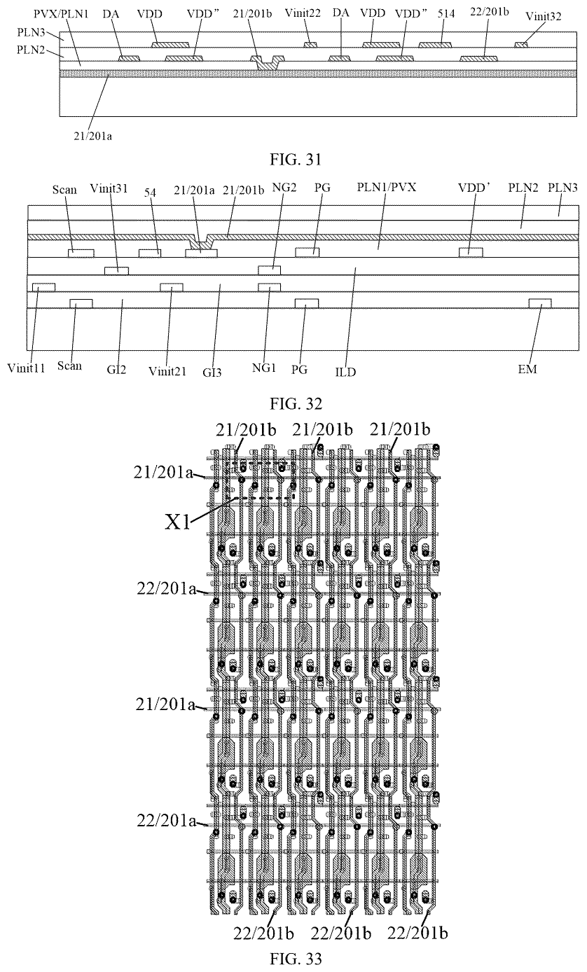

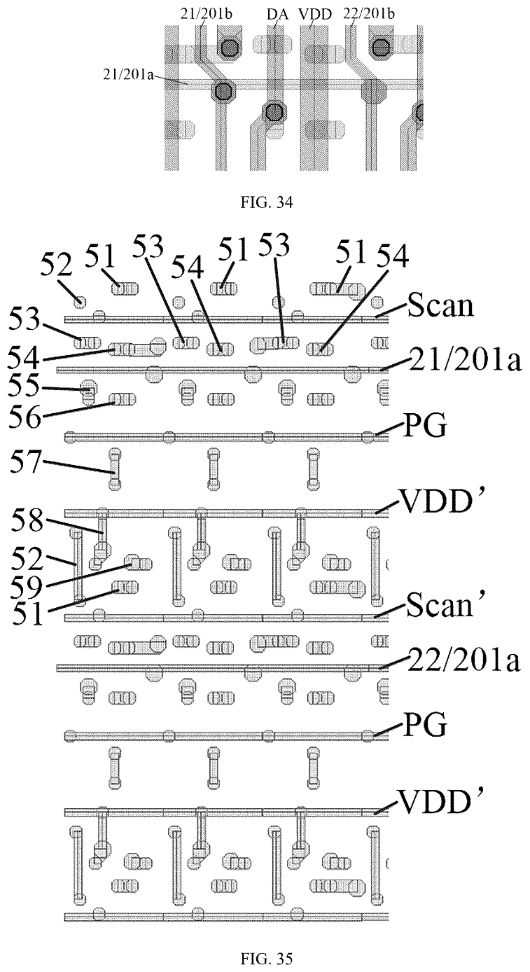

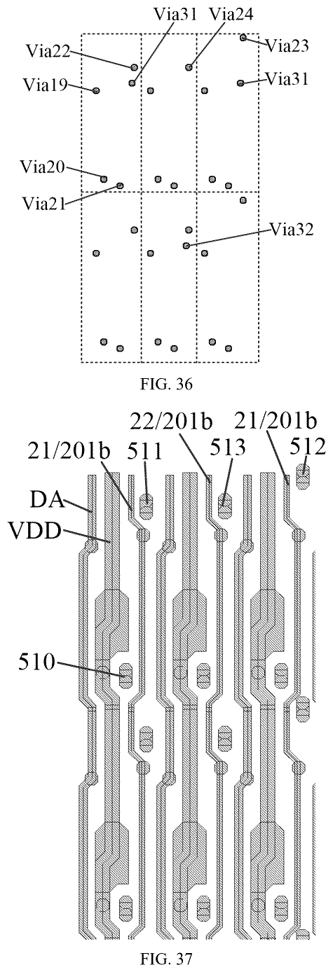

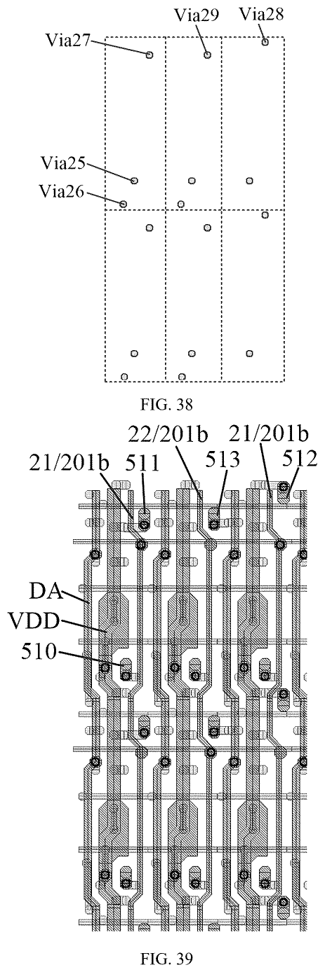

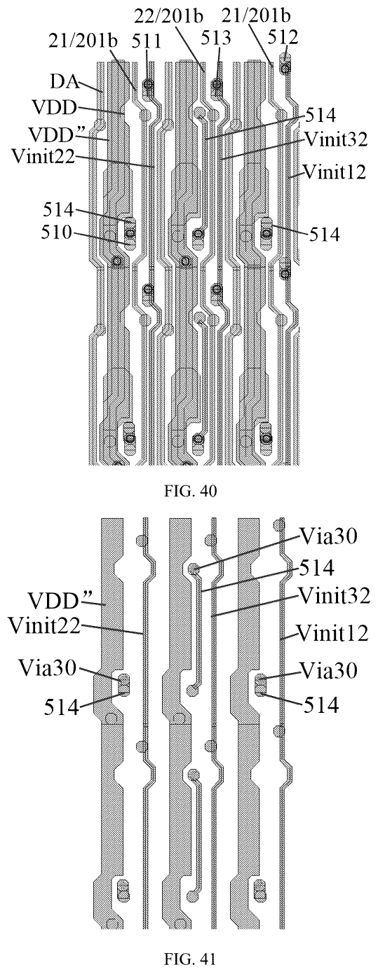

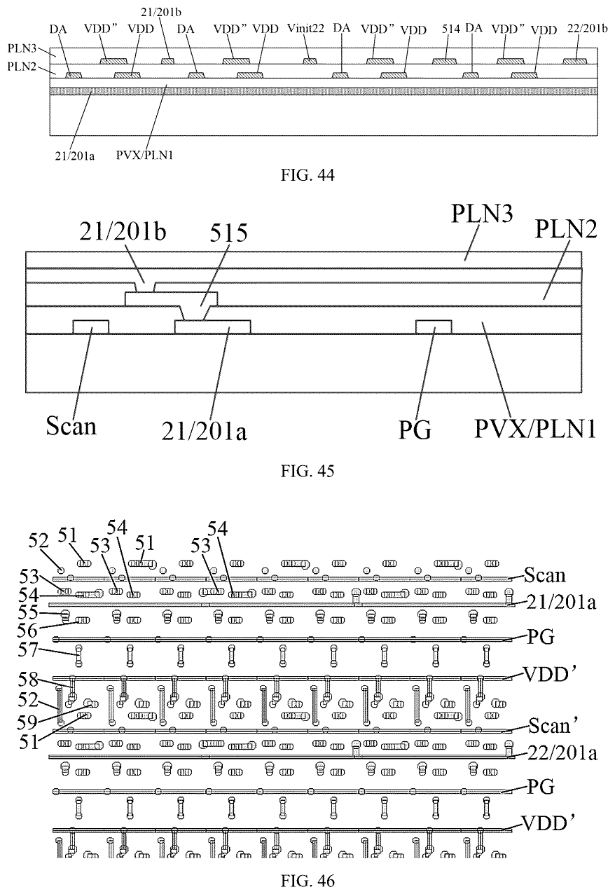

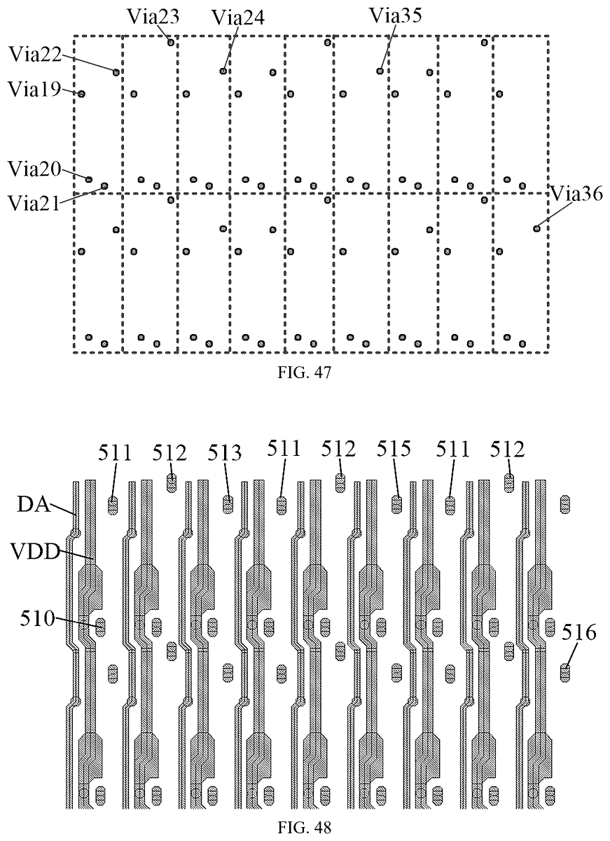

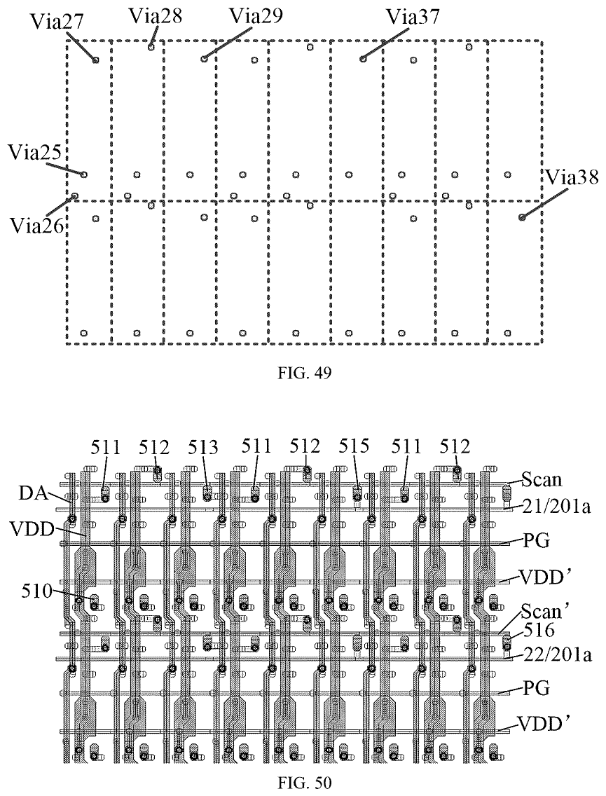

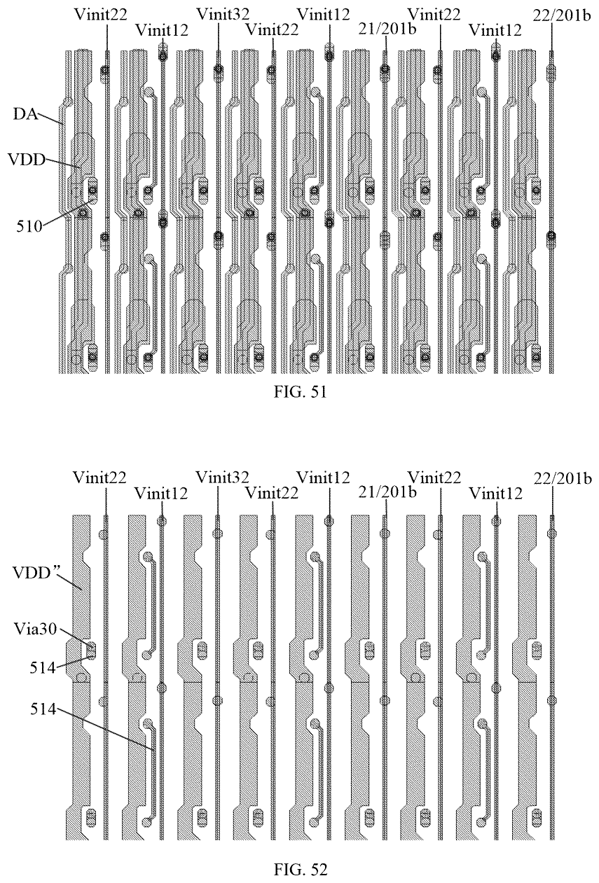

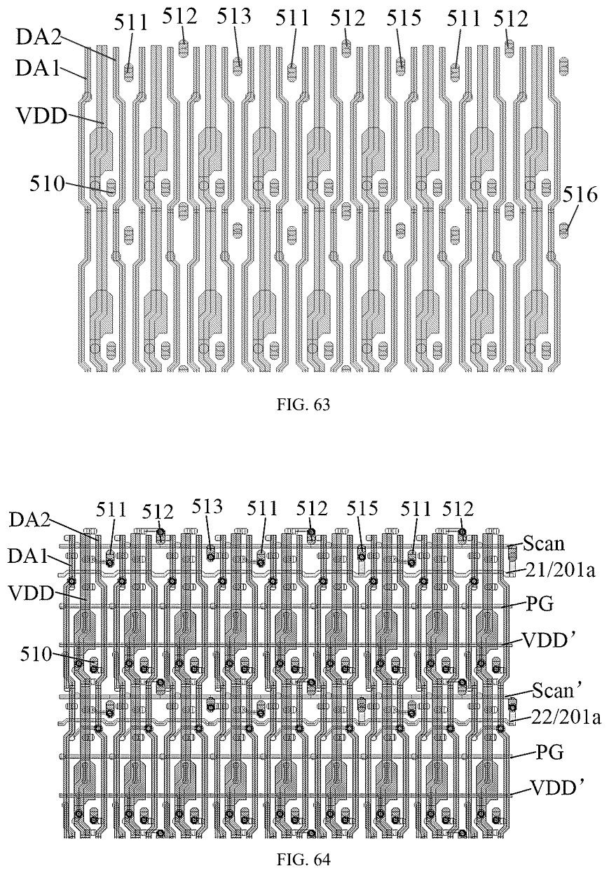

As shown in FIGS. 30 to 52 and FIGS. 59 to 65, in some embodiments, the power compensation section 201 includes multiple second power compensation lines 201b, an extension direction of the second power compensation line intersects with an extension direction of the first power compensation line 201a. The second power compensation lines 201b are coupled to at least some of the first power compensation line 201a, respectively.

For example, the first power compensation line 201a is arranged on the same layer as the second power compensation line 201b. It is worth noting that the first power compensation line 201a and the second power compensation line 201b are arranged on the same layer in the same power signal transmission layer.

For example, the first power compensation line 201a and the second power compensation line 201b are arranged in different layers, and at least a portion of the first power compensation line 201a is located between the second power compensation line 201b and a base substrate of the display panel.

For example, the multiple second power compensation lines 201b are arranged along the second direction, and the second power compensation line 201b include at least a portion extending along the first direction.

For example, the second power compensation line 201b is coupled to the multiple first power compensation lines 201a.

The above configuration enables the power signal transmission layer to form a mesh structure where the first power compensation line 201a and the second power compensation line 201b intersect, thereby further reducing a resistance of the power signal transmission layer and improving the stability of the power signal transmitted by the power signal transmission layer.

More specifically, in the embodiments illustrated in FIGS. 30 to 41, the power compensation section 201 in the power signal transmission layer includes both the first power compensation line 201a and the second power compensation line 201b. In the embodiment, the second power compensation line 201b is laid out in the second source drain metal layer, and the first initialization compensation line Vinit12, the second initialization compensation line Vinit22, and the third initialization compensation line Vinit32 may be laid out in the third source drain metal layer. In the embodiment, each column of sub-pixel driving circuits corresponds to one data line DA.

In the embodiments illustrated in FIGS. 30 to 41, the second initialization compensation line Vinit22, the third initialization compensation line Vinit32, and the first initialization compensation line Vinit12 are sequentially arranged in a cyclical manner along the second direction.

It is worth noting that, as shown in FIGS. 30 to 41, in the layout area of the first column of sub-pixel driving circuits in the figures, the fourth conductive connection part 54 is coupled to the eleventh conductive connection part 511 through a twenty-second via hole Via22, and the eleventh conductive connection part 511 is coupled to the second initialization compensation line Vinit22 through a twenty-seventh via hole Via27.

As shown in FIGS. 30 to 41, in the layout area of the second column of sub-pixel driving circuits in the figures, the third conductive connection part 53 is coupled to the thirteenth conductive connection part 513 through the twenty-fourth via hole Via24, and the thirteenth conductive connection part 513 is coupled to the third initialization compensation line Vinit32 through a twenty-ninth via hole Via29.

As shown in FIGS. 30 to 41, in the layout area of the third column of sub-pixel driving circuits in the figures, the first conductive connection part 51 is coupled to the twelfth conductive connection part 512 through the twenty-third via hole Via23, and the twelfth conductive connection part 512 is coupled to the first initialization compensation line Vinit12 through a twenty-eighth via hole Via28.

As shown in FIGS. 30 to 41, in the layout area of the first and third columns of sub-pixel driving circuits in the figures, the first power compensation line 201a in the first power signal transmission layer 21 is coupled to the second power compensation line 201b in the first power signal transmission layer 21 through a thirty-first via hole Via31. In the layout area of in the second column of the sub-pixel driving circuit in the figures, the first power compensation line 201a in the second power signal transmission layer 22 is coupled to the second power compensation line 201b in the second power signal transmission layer 22 through a thirty-second via hole Via32.

In the embodiments illustrated in FIGS. 42 to 52, the power compensation section 201 in the power signal transmission layer includes both the first power compensation line 201a and the second power compensation line 201b. In the embodiment, the second power compensation line 201b, the first initialization compensation line Vinit12, the second initialization compensation line Vinit22, and the third initialization compensation line Vinit32 are all arranged in the third source drain metal layer. In the embodiment, each column of sub-pixel driving circuits corresponds to one data line DA.

In the embodiments illustrated in FIGS. 42 to 52, the second initialization compensation line Vinit22, the first initialization compensation line Vinit12, the third initialization compensation line Vinit32, the second initialization compensation line Vinit22, the first initialization compensation line Vinit12, the second power compensation line 201b in the first power signal transmission layer 21, the second initialization compensation line Vinit22, the first initialization compensation line Vinit12, and the second power compensation line 201b in the second power signal transmission layer 22 are sequentially arranged in a cyclical manner along the second direction.

As shown in FIGS. 42 to 52, in the layout area of the sixth column of sub-pixel driving circuits in the figures, the first power compensation line 201a in the first power signal transmission layer 21 is coupled to the fifteenth conductive connection part 515 through the thirty fifth via hole Via35, and the fifteenth conductive connection part 515 is coupled to the second power compensation line 201b in the first power signal transmission layer 21 through the thirty seventh via hole Via37.

As shown in FIGS. 42 to 52, in the layout area of the ninth column of sub-pixel driving circuits in the figure, the first power compensation line 201a in the second power signal transmission layer 22 is coupled to the sixteenth conductive connection part 516 through the thirty sixth via hole Via36, and the sixteenth conductive connection part 516 is coupled to the second power compensation line 201b in the second power signal transmission layer 22 through the thirty eighth via hole Via38.

In the embodiments illustrated in FIGS. 59 to 65, the power compensation section 201 in the power signal transmission layer includes both the first power compensation line 201a and the second power compensation line 201b. In the embodiment, the second power compensation line 201b, the first initialization compensation line Vinit12, the second initialization compensation line Vinit22, and the third initialization compensation line Vinit32 are all arranged in the third source drain metal layer. In the embodiment, each column of sub-pixel driving circuits corresponds to two data lines, such as the first data line DA1 and the second data line DA2.

In the embodiments illustrated in FIGS. 59 to 65, the second initialization compensation line Vinit22, the first initialization compensation line Vinit12, the third initialization compensation line Vinit32, the second initialization compensation line Vinit22, the first initialization compensation line Vinit12, the second power compensation line 201b in the first power signal transmission layer 21, the second initialization compensation line Vinit22, the first initialization compensation line Vinit12, and the second power compensation line 201b in the second power signal transmission layer 22 are sequentially arranged in a cyclical manner along the second direction.

As shown in FIGS. 6, 30, and 53, in some embodiments, the sub-pixels include sub-pixel driving circuits, and the multiple sub-pixel driving circuits included in the multiple sub-pixels are divided into multiple rows of sub-pixel driving circuits.

An orthographic projection of the first power compensation line 201a onto the base substrate of the display panel overlaps at least partially with the orthographic projection of a corresponding row of sub-pixel driving circuits onto the base substrate.

There are n rows of sub-pixel driving circuits between two rows of sub-pixel driving circuits corresponding to two adjacent first power compensation lines 201a, where n is greater than or equal to 0.

For example, the multiple sub-pixel driving circuits included in the multiple of sub-pixels are distributed in an array. The multiple sub-pixel driving circuits may be divided into multiple rows of sub-pixel driving circuits and multiple columns of sub-pixel driving circuits. The multiple rows of sub-pixel driving circuits are arranged along the first direction, and each row of sub-pixel driving circuits includes multiple sub-pixel driving circuits arranged along the second direction. The multiple columns of sub-pixel driving circuits are arranged along the second direction, and each column of sub-pixel driving circuits includes multiple sub-pixel driving circuits arranged along the first direction.

For example, the orthographic projection of the first power compensation line 201a onto the base substrate of the display panel overlaps at least partially with an orthographic projection of each of sub-pixel driving circuits in a corresponding row of sub-pixel driving circuits onto the base substrate; or, the orthographic projection of the first power compensation line 201a onto the base substrate of the display panel overlaps at least partially with orthographic projections of some of sub-pixel driving circuits in a corresponding row of sub-pixel driving circuits onto the base substrate

For example, there are n rows of sub-pixel drive circuits between two rows of sub-pixel drive circuits corresponding to two adjacent first power compensation lines 201a, where n is an integer greater than or equal to 0. For example, n values include 1, 2, 3, 4, 5, etc., but are not limited to these.

The above arrangement method enables the first power compensation lines 201a to be laid out at an appropriate density in the display area 10. This not only helps to reduce a resistance of the power signal transmission layer, but also better balances the layout complexity of the display panel in the display area 10, thereby reducing the overall layout difficulty of the display panel.

As shown in FIGS. 6, 30, and 53, in some embodiments, the sub-pixel driving circuit includes a driving transistor (such as the third transistor T3), a local refresh control transistor (such as the eighth transistor T8), and a second reset transistor (such as the seventh transistor T7). A gate electrode of the driving transistor is coupled to a second electrode of the local refresh control transistor, and a second electrode of the driving transistor is coupled to a second electrode of the second reset transistor.

The display panel further includes a second initialization signal line Vinit21 and a local refresh control line (such as the second scanning line NG), where the second initialization signal line Vinit21 is coupled to a first electrode of a second reset transistor included in each of sub-pixel driving circuits in a corresponding row of sub-pixel driving circuits. The local refresh control line is coupled to a gate electrode of a local refresh control transistor included in each of sub-pixel driving circuits in a corresponding row of sub-pixel driving circuits.

At least a portion of the orthographic projection of the first power compensation line 201a onto the base substrate is located between an orthographic projection of the second initialization signal line Vinit21 onto the base substrate and an orthographic projection of the local refresh control line onto the base substrate.

For example, the display panel includes multiple second initialization signal lines Vinit21, and the multiple second initialization signal lines Vinit21 are arranged in sequence along the first direction. The second initialization signal line Vinit21 include at least a portion extending along the second direction. The multiple second initialization signal lines Vinit21 correspond one-to-one with multiple rows of sub-pixel driving circuits, but are not limited thereto.

For example, the display panel includes multiple local refresh control lines arranged in sequence along the first direction, the local refresh control line includes at least a portion extending along the second direction, and the multiple local refresh control lines corresponding one-to-one with multiple rows of sub-pixel driving circuits, but not limited to these.

By way of example, an orthographic projection of the first power compensation line 201a onto the base substrate is located between the orthographic projection of the second initialization signal line Vinit21 onto the base substrate and the orthographic projection of the local refresh control line onto the base substrate.

The above arrangement method enables the first power compensation lines 201a to be laid out in a larger layout space between the second initialization signal line Vinit21 and the local refresh control line, which is conducive to reducing the layout difficulty of the display panel and improving the layout yield.

As shown in FIGS. 1 to 52, in some embodiments, the display panel further includes data lines DA, and the data line is coupled to each of sub-pixel driving circuits in a corresponding column of sub-pixel driving circuits.

For example, the display panel includes multiple data lines DA arranged along the second direction, the data line DA includes at least a portion extending along the first direction, and the multiple data lines DA correspond one-to-one with multiple columns of sub-pixel driving circuits, but not limited to these.

For example, the sub-pixel driving circuit includes a driving transistor and a data writing transistor (such as the fourth transistor), a second electrode of the data writing transistor is coupled to the first electrode of the driving transistor. The data line DA is coupled to a first electrode of a data writing transistor included in each of sub-pixel driving circuits in a corresponding column of sub-pixel driving circuits.

As shown in FIGS. 53 to 65, in some embodiments, the display panel further includes multiple first data lines DA1 and multiple second data lines DA2. The first data line DA1 is coupled to each of odd-numbered sub-pixel driving circuits in a corresponding column of sub-pixel driving circuits, and the second data line DA2 is coupled to each of even-numbered sub-pixel driving circuits in a corresponding column of sub-pixel driving circuits. An orthographic projection of the first data line DA1 onto the base substrate is located on a first side of an orthographic projection of the column of sub-pixel driving circuits coupled to the first data line onto the base substrate, and an orthographic projection of the second data line DA2 onto the base substrate is located on a second side of an orthographic projection of the column of sub-pixel driving circuits coupled to the second data line onto the base substrate. The second side is opposite to the first side.

For example, the first data line DA1 includes at least a portion extending along the first direction, and the second data line DA2 includes at least a portion extending along the first direction. The first data line DA1 and the second data line DA2 are alternately arranged along the second direction.

For example, the multiple first data lines DA1 and the multiple second data lines DA2 are divided into multiple groups of data lines DA, and the multiple groups of data lines DA are arranged along the second direction. Each group of data lines DA includes the first data line DA1 and the second data line DA2 that are adjacent to each other. The multiple groups of data lines DA correspond one-to-one with the multiple columns of sub-pixel driving circuits. In the same group of data line DAs, the first data line DA1 is coupled to each of odd-numbered sub-pixel driving circuits in a corresponding column of sub-pixel driving circuits, and the second data line DA2 is coupled to each of even-numbered sub-pixel driving circuits in a corresponding column of sub-pixel driving circuits.

As shown in FIGS. 6 to 65, in some embodiments, the multiple sub-pixel driving circuits included in the multiple sub-pixels are divided into multiple columns of sub-pixel driving circuit; orthographic projections of m columns of sub-pixel driving circuits onto the base substrate are located between orthographic projections of two adjacent second power compensation lines 201b onto the base substrate, where m is greater than or equal to 1.

By way of example, an orthographic projection of at least a portion of the second power compensation line 201b onto the base substrate is located between orthographic projections of two adjacent columns of sub-pixel driving circuits onto the base substrate.

For example, an orthographic projection of the second power compensation line 201b onto the base substrate is located on a side of the column of sub-pixel driving circuit along the second direction.

For example, orthographic projections of m columns of sub-pixel driving circuits onto the base substrate are located between orthographic projections of two adjacent second power compensation lines 201b onto the base substrate, where m is an integer greater than or equal to 1. For example, m values include 1, 2, 3, 4, 5, etc., but are not limited to these.

In the above arrangement method, the second power compensation lines 201b can be laid out at an appropriate density in the display area 10, which not only helps to reduce a resistance of the power signal transmission layer, but also better balances the layout complexity of the display panel in the display area 10, thereby reducing the overall layout difficulty of the display panel.

As shown in FIG. 30, in some embodiments, the sub-pixel driving circuit includes a driving transistor and a compensation transistor (such as the second transistor T2), and a second electrode of the driving transistor is coupled to a first electrode of the compensation transistor.

The display panel further includes data lines DA, and the data line DA is coupled to each of sub-pixel driving circuits in a corresponding column of sub-pixel driving circuits.

At least a portion of the orthographic projection of the second power compensation line 201b onto the base substrate is located between an orthographic projection of an active layer of the compensation transistor (such as the second active layer pattern 42) onto the base substrate and an orthographic projection of a data line DA coupled to a sub-pixel driving circuit adjacent to the compensation transistor onto the base substrate.

The above arrangement method enables the second power compensation lines 201b to be laid out in a larger layout space between the compensation transistor and the data line DA, which is conducive to reducing the layout difficulty of the display panel and improving the layout yield.

As shown in FIG. 30, in some embodiments, the sub-pixel driving circuit includes a driving transistor and a light emission control transistor (such as the sixth transistor T6), and the second electrode of the driving transistor is coupled to a first electrode of the light emission control transistor.

The display panel further includes data lines DA, and the data line DA is coupled to each of sub-pixel driving circuits in a corresponding column of sub-pixel driving circuits.

At least a portion of the orthographic projection of the second power compensation line 201b onto the base substrate is located between an orthographic projection of the active layer (such as the sixth active layer pattern 46) of the light emission control transistor onto the base substrate and an orthographic projection of a data line DA coupled to a sub-pixel driving circuit adjacent to the compensation transistor onto the base substrate.

The above arrangement method enables the second power compensation lines 201b to be laid out in a larger layout space between the light emission control transistor and the data line DA, which is conducive to reducing the layout difficulty of the display panel and improving the layout yield.

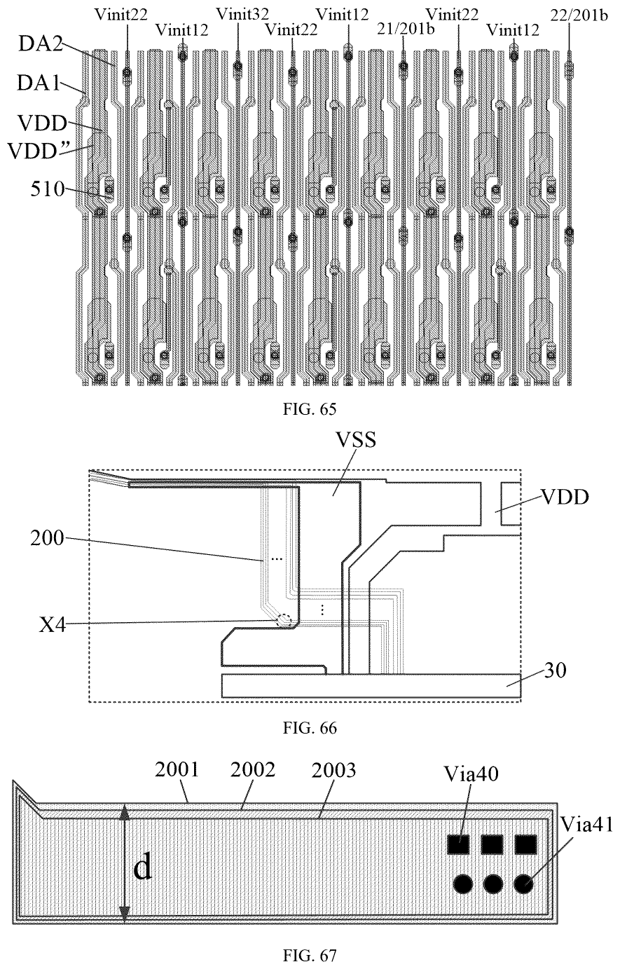

As shown in FIG. 65, in some embodiments, the display panel further includes multiple first data lines DA1 and multiple second data lines DA2. The first data line DA1 is coupled to each of odd-numbered sub-pixel driving circuits in a corresponding column of sub-pixel driving circuits, and the second data line DA2 is coupled to each of even-numbered sub-pixel driving circuits in a corresponding column of sub-pixel driving circuits; an orthographic projection of the first data line DA1 onto the base substrate is located on a first side of an orthographic projection of the column of sub-pixel driving circuits coupled to the first data line onto the base substrate, and an orthographic projection of the second data line DA2 onto the base substrate is located on a second side of an orthographic projection of the column of sub-pixel driving circuits coupled to the second data line onto the base substrate. The second side is opposite to the first side.

At least a portion of an orthographic projection of the second power compensation line 201b onto the base substrate is located between orthographic projections of the first data line DA1 and the second data line DA2 adjacent to each other onto the base substrate.

For example, the multiple first data lines DA1 and the multiple second data lines DA2 are divided into multiple groups of data lines DA, and at least a portion of the second power compensation line 201b is located between orthographic projections of adjacent groups of data lines DA onto the base substrate.

The above arrangement method enables the second power compensation lines 201b to be laid out in a larger layout space between adjacent groups of data line DAs, which is conducive to reducing the layout difficulty of the display panel and improving the layout yield.

As shown in FIGS. 6 to 65, in some embodiments, the display panel includes a first power signal transmission layer 21 and a second power signal transmission layer 22; and the first power compensation line 201a included in the first power signal transmission layer 21 and the first power compensation line 201a included in the second power signal transmission layer 22 are alternately arranged along the first direction.

For example, a first power signal transmitted by the first power signal transmission layer 21 includes a high-level power signal, and a second power signal transmitted by the second power signal transmission layer 22 includes a low-level power signal, but are not limited thereto.

For example, the first power signal transmission layer 21 is coupled to each of shift register units, and is configured to provide the first power signal to the coupled shift register units. The second power signal transmission layer 22 is coupled to each of shift register units, and is configured to provide a second power signal to the coupled shift register units.

By way of example, the first power signal transmission layer 21 includes a portion located in the display area 10 and a portion located in the peripheral area 11, and the portion located in the display area 10 is coupled to the portion located in the peripheral area 11. The second power signal transmission layer 22 includes a portion located in the display area 10 and a portion located in the peripheral area 11, where the portion located in the display area 10 is coupled to the portion located in the peripheral area 11.

For example, an orthographic projection of the first power compensation line 201a included in the first power signal transmission layer 21 onto the base substrate overlaps at least partially with an orthographic projection of an odd-numbered row of sub-pixel driving circuits onto the base substrate, and an orthographic projection of the first power compensation line 201a included in the second power signal transmission layer 22 onto the base substrate overlaps at least partially with an orthographic projection of an even-numbered row of sub-pixel driving circuits onto the base substrate. Alternatively, an orthographic projection of the first power compensation line 201a included in the first power signal transmission layer 21 onto the base substrate overlaps at least partially with an orthographic projection of an even-numbered row of sub-pixel driving circuits onto the base substrate, and an orthographic projection of the first power compensation line 201a included in the second power signal transmission layer 22 onto the base substrate overlaps at least partially with an orthographic projection of an odd-numbered row of sub-pixel driving circuits onto the base substrate.

In the above arrangement, the first power compensation line 201a included in the first power signal transmission layer 21 and the first power compensation line 201a included in the second power signal transmission layer 22 are arranged alternately along the first direction, which can better ensure the uniformity of the layout of the first power compensation line 201a included in each power signal transmission layer within the display area 10. Furthermore, the layout space can be better utilized within the display area 10 to enable the first power signal transmission layer 21 and the second power signal transmission layer 22 to have lower resistances.

As shown in FIGS. 30 to 52 and FIGS. 59 to 65, in some embodiments, the second power compensation lines 201b included in the first power signal transmission layer 21 and the second power compensation lines 201b included in the second power signal transmission layer 22 are alternately arranged along the second direction, and the second direction intersects with the first direction.

For example, the second power compensation line 201b included in the first power signal transmission layer 21 is located on a side of a corresponding odd-numbered column of sub-pixel driving circuits, and the second power compensation line 201b included in the second power signal transmission layer 22 is located on a side of a corresponding even-numbered column of sub-pixel driving circuits; or, the second power compensation line 201b included in the first power signal transmission layer 21 is located on a side of a corresponding even-numbered column of sub-pixel driving circuits, and the second power compensation line 201b included in the second power signal transmission layer 22 is located on a side of a corresponding odd-numbered column of sub-pixel driving circuits.

The second power compensation lines 201b included in the first power signal transmission layer 21 and the second power compensation lines 201b included in the second power signal transmission layer 22 are alternately arranged along the second direction, which can better ensure the uniformity of the layout of the second power compensation lines 201b included in each power signal transmission layer within the display area 10; and can better utilize the layout space within the display area 10 to reduce resistances of the first power signal transmission layer 21 and the second power signal transmission layer 22.

In some embodiments, the sub-pixel driving circuit includes a first reset transistor (such as the first transistor T1), and a second electrode of the first reset transistor is coupled to a gate electrode of the driving transistor.

The display panel further includes a first initialization signal transmission layer structure Vinit1, and the first initialization signal transmission layer structure Vinit1 includes multiple first initialization signal lines Vinit11 and multiple first initialization compensation lines Vinit12. An extension direction of first initialization compensation line Vinit12 intersects with an extension direction of the first initialization signal line Vinit11. The first initialization signal line Vinit11 is respectively coupled to a first electrode of the first reset transistor included in each of sub-pixel driving circuits in a corresponding row of sub-pixel driving circuits. The first initialization compensation line Vinit12 is coupled to at least a portion of the first initialization signal line Vinit11. As shown in FIGS. 10 to 28, it should be noted that the first conductive connection part 51 is coupled to the first initialization signal line Vinit11 through the first via hole Via1. The first conductive connection part 51 is coupled to the twelfth conductive connection part 512 through the twenty-third via hole Via23, and the twelfth conductive connection part 512 is coupled to the first initialization compensation line Vinit12 through the twenty-eighth via hole Via28.

An orthographic projection of the first initialization compensation line Vinit12 onto the base substrate and the orthographic projection of the second power compensation line 201b included in the first power signal transmission layer 21 onto the base substrate are alternately arranged along the second direction; and/or, an orthographic projection of the first initialization compensation line Vinit12 onto the base substrate and the orthographic projection of the second power compensation line 201b included in the second power signal transmission layer 22 onto the base substrate are alternately arranged along the second direction.

In some embodiments, the sub-pixel driving circuit includes a second reset transistor (such as a seventh transistor T7), the second electrode of which is coupled to the second electrode of the driving transistor.

The display panel further includes a second initialization signal transmission layer structure Vinit2, and the second initialization signal transmission layer structure Vinit2 includes multiple second initialization signal lines Vinit21 and multiple second initialization compensation lines Vinit22. An extension direction of the second initialization compensation line Vinit22 intersects with an extension direction of the second initialization signal line Vinit21. The second initialization signal line Vinit21 is coupled to a first electrode of a second reset transistor included in each of sub-pixel driving circuits in a corresponding row of sub-pixel driving circuits. The second initialization compensation line Vinit22 is coupled to at least a portion of the second initialization signal line Vinit21. As shown in FIGS. 10 to 28, it should be noted that the fourth conductive connection part 54 is coupled to the first electrode of the seventh transistor T7 through the sixth via hole Via6, the fourth conductive connection part 54 is coupled to the second initialization signal line Vinit21 through the seventh via hole Via7, the fourth conductive connection part 54 is coupled to the eleventh conductive connection part 511 through the second twelfth via hole Via22, and the eleventh conductive connection part 511 is coupled to the second initialization compensation line Vinit22 through the twenty-seventh via hole Via27.

The orthographic projection of the second initialization compensation line Vinit22 onto the base substrate and the orthographic projection of the second power compensation line 201b included in the first power signal transmission layer 21 onto the base substrate are alternately arranged along the second direction; and/or, the orthographic projection of the second initialization compensation line Vinit22 onto the base substrate and the orthographic projection of the second power compensation line 201b included in the second power signal transmission layer 22 onto the base substrate are alternately arranged along the second direction.

In some embodiments, the sub-pixel driving circuit includes a third reset transistor (such as the ninth transistor T9), the second electrode of the third reset transistor is coupled to the first electrode of the driving transistor.

The display panel further includes a third initialization signal transmission layer structure Vinit3, and the third initialization signal transmission layer structure Vinit3 includes multiple third initialization signal lines Vinit31 and multiple third initialization compensation lines Vinit32. An extension direction of the third initialization compensation line Vinit32 intersects with an extension direction of the third initialization signal line Vinit31. The third initialization signal line Vinit31 is coupled to a first electrode of the third reset transistor included in each of sub-pixel driving circuits in a corresponding row of sub-pixel driving circuits. The third initialization compensation lines Vinit32 are coupled to at least some of the third initialization signal lines Vinit31, respectively. As shown in FIGS. 10 to 28, and 35 to 41, it should be noted that the third conductive connection part 53 is coupled to the first electrode of the ninth transistor T9 through the fifth via hole Via5, the third conductive connection part 53 is coupled to the third initialization signal line Vinit31 through the sixteenth via hole Via16, the third conductive connection part 53 is coupled to the thirteenth conductive connection part 513 through the twenty-fourth via hole Via24, and the thirteenth conductive connection part 513 is coupled to the third initialization compensation line Vinit32 through the twenty-ninth via hole Via29.

An orthographic projection of the third initialization compensation line Vinit32 onto the base substrate and the orthographic projection of the second power compensation line 201b included in the first power signal transmission layer 21 onto the base substrate are alternately arranged along the second direction; and/or, an orthographic projection of the third initialization compensation line Vinit32 onto the base substrate and the orthographic projection of the second power compensation line 201b included in the he second power signal transmission layer 22 onto the base substrate are alternately arranged along the second direction.

For example, the second power compensation line 201b included in the first power signal transmission layer 21 and the second power compensation line 201b included in the second power signal transmission layer 22 are arranged on the same layer as the first initialization compensation line Vinit12, the second initialization compensation line Vinit22, or the third initialization compensation line Vinit32, but not limited to this.

The second power compensation line 201b included in each power signal transmission layer, the same layer as the first initialization compensation line Vinit12, the second initialization compensation line Vinit22, and/or the third initialization compensation line Vinit32 are is arranged alternately, which not only helps to improve the uniformity of the layout of the second power compensation line 201b in each power signal transmission layer and each initialization compensation line included within the display area 10. Moreover, the layout space within the display area 10 can be better utilized to achieve low resistances of the first power signal transmission layer 21 and the second power signal transmission layer 22.

As shown in FIGS. 30 to 41, in some embodiments, the sub-pixel driving circuit includes a first reset transistor, a second reset transistor, and a third reset transistor; the second electrode of the first reset transistor is coupled to the gate electrode of the driving transistor, the second electrode of the second reset transistor is coupled to the second electrode of the driving transistor, and the second electrode of the third reset transistor is coupled to the first electrode of the driving transistor.

The display panel further includes a first initialization signal transmission layer structure Vinit1, a second initialization signal transmission layer structure Vinit2, and a third initialization signal transmission layer structure Vinit3.

The first initialization signal transmission layer structure Vinit1 includes multiple first initialization signal lines Vinit11 and multiple first initialization compensation lines Vinit12. An extension direction of the first initialization compensation line Vinit12 intersects with an extension direction of the first initialization signal line Vinit11. The first initialization signal line Vinit11 is coupled to a first electrode of a first reset transistor included in each of sub-pixel driving circuits in a corresponding row of sub-pixel driving circuits. The first initialization compensation lines Vinit12 are coupled to at least some of the first initialization signal line Vinit11, respectively.

The second initialization signal transmission layer structure Vinit2 includes multiple second initialization signal lines Vinit21 and multiple second initialization compensation lines Vinit22, and an extension direction of the second initialization compensation line Vinit22 intersects with an extension direction of the second initialization signal line Vinit21. The second initialization signal line Vinit21 is coupled to a first electrode of a second reset transistor included in each of sub-pixel driving circuits in a corresponding row of sub-pixel driving circuits. The second initialization compensation lines Vinit22 are coupled to at least some of the second initialization signal line Vinit21, respectively.

The third initialization signal transmission layer structure Vinit3 includes multiple third initialization signal lines Vinit31 and multiple third initialization compensation lines Vinit32, and an extension direction of the third initialization compensation line Vinit32 intersects with an extension direction of the third initialization signal line Vinit31. The third initialization signal line Vinit31 is coupled to a first electrode of a third reset transistor included in each of sub-pixel driving circuits in a corresponding row of sub-pixel driving circuits. The third initialization compensation lines Vinit32 are coupled to at least some of the third initialization signal line Vinit31, respectively.

The second initialization compensation line Vinit22, the third initialization compensation line Vinit32, and the first initialization compensation line Vinit12 are sequentially arranged in a cyclical manner along the second direction. The second initialization compensation line Vinit22, the third initialization compensation line Vinit32, and the first initialization compensation line Vinit12 are arranged in a same layer and made of a same material.

The second power compensation line 201b included in the first power signal transmission layer 21 and the second power compensation line 201b included in the second power signal transmission layer 22 are arranged in a same layer and made of a same material, and are arranged in the layer different from the first initialization compensation line Vinit12.

For example, the display panel includes a first source drain metal layer, a second source drain metal layer, and a third source drain metal layer stacked in sequence along a direction away from the base substrate; and the first power compensation line 201a included in the first power signal transmission layer 21 and the first power compensation line 201a included in the second power signal transmission layer 22 are both arranged in a same layer and made of a same material as the first source drain metal layer. The second power compensation line 201b included in the first power signal transmission layer 21 and the second power compensation line 201b included in the second power signal transmission layer 22 are both arranged in a same layer and made of a same material as the second source drain metal layer. The second initialization compensation line Vinit22, the third initialization compensation line Vinit32, and the first initialization compensation line Vinit12 are all arranged in a same layer and made of a same material as the third source drain metal layer.

The above arrangement method is not only beneficial for improving the uniformity of the layout of the second power compensation line 201b included in each power signal transmission layer and the initialization compensation lines within the display area 10; and can better utilize the layout space within the display area 10 to achieve low resistances of first power signal transmission layer 21 and second power signal transmission layer 22. Moreover, the above arrangement method ensures that each power signal transmission layer and each initialization signal transmission layer has low resistance and transmission signal stability, and appropriately reduces the wiring density of the second power compensation line 201b in each power signal transmission layer and each initialization compensation line, thereby simplifying the layout complexity of the display panel, and reducing the layout difficulty of the display panel.

As shown in FIGS. 42 to 52 and FIGS. 59 to 65, in some embodiments, the sub-pixel driving circuit includes a first reset transistor, a second reset transistor, and a third reset transistor. A second electrode of the first reset transistor is coupled to the gate electrode of the driving transistor, a second electrode of the second reset transistor is coupled to the second electrode of the driving transistor, and a second electrode of the third reset transistor is coupled to the first electrode of the driving transistor.

The display panel further includes a first initialization signal transmission layer structure Vinit1, a second initialization signal transmission layer structure Vinit2, and a third initialization signal transmission layer structure Vinit3.

The first initialization signal transmission layer structure Vinit1 includes multiple first initialization signal lines Vinit11 and multiple first initialization compensation lines Vinit12. An extension direction of first initialization compensation line Vinit12 intersects with an extension direction of the first initialization signal line Vinit11. The first initialization signal line Vinit11 is coupled to a first electrode of the first reset transistor included in each of the sub-pixel driving circuits in a corresponding row of sub-pixel driving circuits. The first initialization compensation lines Vinit12 are coupled to at least some of the first initialization signal line Vinit11, respectively.

The second initialization signal transmission layer structure Vinit2 includes multiple second initialization signal lines Vinit21 and multiple second initialization compensation lines Vinit22. An extension direction of the second initialization compensation line Vinit22 intersects with an extension direction of the second initialization signal lines Vinit21. The second initialization signal line Vinit21 is coupled to a first electrode of the second reset transistor included in each of the sub-pixel driving circuits in a corresponding row of sub-pixel driving circuits. The second initialization compensation lines Vinit22 are coupled to at least some of the second initialization signal line Vinit21, respectively.

The third initialization signal transmission layer structure Vinit3 includes multiple third initialization signal lines Vinit31 and multiple third initialization compensation lines Vinit32. An extension direction of the third initialization compensation line Vinit32 intersects with an extension direction of the third initialization signal lines Vinit31. The third initialization signal line Vinit31 is coupled to a first electrode of the third reset transistor included in each of the sub-pixel driving circuits in a corresponding row of sub-pixel driving circuits. The third initialization compensation lines Vinit32 are coupled to at least some of the third initialization signal line Vinit31, respectively.

The multiple first initialization compensation lines Vinit12, the multiple second initialization compensation lines Vinit22, the multiple third initialization compensation lines Vinit32, the multiple second power compensation lines 201b included in the first power signal transmission layer 21, and the multiple second power compensation lines 201b included in the second power signal transmission layer 22 are divided into multiple first compensation groups, multiple second compensation groups, and multiple third compensation groups, respectively. The first compensation group, the second compensation group, and the third compensation group are sequentially arranged in a cyclical manner along the second direction.

The first compensation group includes the second initialization compensation line Vinit22, the first initialization compensation line Vinit12, and the third initialization compensation line Vinit32 arranged in sequence. The second compensation group includes the second initialization compensation line Vinit22, the first initialization compensation line Vinit12, and the second power compensation line 201b included in the first power signal transmission layer 21 arranged in sequence. The second compensation group includes the second initialization compensation line Vinit22, the first initialization compensation line Vinit12, and the second power compensation line 201b included in the second power signal transmission layer 22 arranged in sequence.

For example, the display panel includes a first source drain metal layer, a second source drain metal layer, and a third source drain metal layer stacked in sequence along a direction away from the base substrate. The first power compensation line 201a included in the first power signal transmission layer 21 and the first power compensation line 201a included in the second power signal transmission layer 22 are both arranged in a same layer and made of a same material as the first source drain metal layer. The second power compensation line 201b included in the first power signal transmission layer 21, the second power compensation line 201b included in the second power signal transmission layer 22, the second initialization compensation line Vinit22, the third initialization compensation line Vinit32, and the first initialization compensation line Vinit12 are all arranged in a same layer and made of a same material as the third source drain metal layer.

The above arrangement method is not only beneficial for improving the uniformity of the layout of the second power compensation line 201b included in each power signal transmission layer and the initialization compensation lines within the display area 10, and can better utilize the layout space within the display area 10 to achieve low resistances of the first power signal transmission layer 21 and the second power signal transmission layer 22. Moreover, the above arrangement method ensures that each power signal transmission layer and each initialization signal transmission layer has low resistance and transmission signal stability, while appropriately reducing the wiring density of the second power compensation line 201b and each initialization compensation line in each power signal transmission layer, thereby simplifying the layout complexity of the display panel, and reducing the layout difficulty of the display panel.

As shown in FIGS. 66 and 67, in some embodiments, a line width d of the power bus section 200 satisfies: 550 μm≤d≤150 μm.

For example, line widths d of the power bus portions 200 in both the first power signal transmission layer 21 and the second power signal transmission layer 22 satisfy the above range.

For example, the line width d of the power bus section 200 may take values of 60 μm, 70 μm, 80 μm, 90 μm, 100 μm, 110 μm, 120 μm, 130 μm, and 140 μm, but is not limited to these.

For example, a line width of an orthographic projection of the power bus section 200 onto the base substrate is between 50 μm and 150 μm, which may include endpoint values.

Setting the line width of the power bus section 200 within the above range further reduces the resistance of the power signal transmission layer and improves the stability of the transmission signal of the power signal transmission layer.

As shown in FIGS. 66 and 67, in some embodiments, the power bus section 200 includes a first bus layer 2001, a second bus layer 2002, and a third bus layer 2003 stacked in sequence along a direction away from the base substrate of the display panel. The third bus layer 2003 is coupled to each of the first bus layer 2001 and the second bus layer 2002.

For example, the third bus layer 2003 is coupled to the first bus layer 2001 through a fortieth via hole Via40, and the third bus layer 2003 is coupled to the second bus layer 2002 through a forty-first via hole Via41.

For example, the power bus portions 200 in the first power signal transmission layer 21 and the second power signal transmission layer 22 both adopt a structure of three layers of bus as described above.

For example, the display panel further includes a first gate metal layer, a second gate metal layer, and a first source drain metal layer stacked in sequence along a direction away from the base substrate. The first bus layer 2001 is arranged in a same layer and made of a same material as the first gate metal layer, the second bus layer 2002 is arranged in a same layer and made of a same material as the second gate metal layer, and the third bus layer 2003 is arranged in a same layer and made of a same material as the first source drain metal layer. This arrangement method enables multiple bus layers to be formed simultaneously with the existing film layers in the display panel in a same patterning process, thereby simplifying the manufacturing process of the display panel.

The above structure is adopted for the power bus section 200, which further reduces the resistance of the power signal transmission layer and improves the stability of signal transmission in the power signal transmission layer.

An embodiment of the present disclosure further provides a display device, including the display panel provided in the above embodiments.

For example, the display device includes an organic light emitting diode display device, but is not limited to this.

It should be noted that the display device may be any product or component with a display function, such as a television, a monitor, a digital photo frame, a mobile phone, a tablet computer, etc. The display device further includes a flexible circuit board, a printed circuit board, and a back plate.

In the display panel provided by the above embodiments, the power signal transmission layer coupled to the shift register unit includes a portion located in the display area 10 and a portion located in the peripheral area 11, so that the power signal transmission layer can be laid out in both the display area 10 and the peripheral area 11 of the display panel. In this way, a larger layout space may be used inside the display panel, to enable the power signal transmission layer to have a smaller resistance value, which makes a power signal transmitted by the power signal transmission layer more stable, and effectively prevents a problem of a voltage jump of a power signal caused by a difference between loads of shift register units controlling different refresh rate areas, thereby avoiding a display difference between different refresh rate display areas 10. The display panel provided in the embodiment of the present disclosure adopts the above structure for the power signal transmission layer, which can prevent the problem of a bright band at the display boundary caused by a difference in loads between different refresh frequencies during local refreshing.

The display device provided in an embodiment of the present disclosure also has the above-mentioned beneficial effects when including the display panel, which will not be repeated here.

It should be noted that extension of a signal line in a certain direction refers to that the signal line includes a main part and a secondary part connected to the main part, the main part is a line, a line segment or a bar shaped body, the main part extends in a certain direction, and an length of the main part extending in the certain direction is greater than a length of the secondary part extending in another direction.

It should be noted that the term “same layer” in the embodiments of the present disclosure refers to film layers located on the same structural layer. Alternatively, for example, film layers on the same layer may be formed through a same film-forming process to create a specific pattern, and then patterned using a same mask through a single patterning process to form the layer structure. Depending on the specific pattern, a single patterning process may include multiple exposures, developments, or etching processes, and the specific pattern in the formed layer structure may be continuous or discontinuous. These specific shapes may also be at different heights or have different thicknesses.

In the various method embodiments of the present disclosure, the serial number of each step cannot be used to define the order of each step, and for a person of ordinary skill in the art, without involving any inventive effort, changes in the order of each step are also within the scope of the present disclosure.

It should be noted that the various embodiments described herein are described in a progressive manner with reference to the same or similar parts throughout the various embodiments, with each embodiment focusing on differences from the other embodiments. In particular, the embodiments are described more simply because they are approximately similar to the product embodiments, with reference to the partial description of the product embodiments.

Unless defined otherwise, technical or scientific terms used in the present disclosure shall have the ordinary meaning as understood by one of ordinary skill in the art to which the present disclosure belongs. Such terms as “first”, “second” used in the present disclosure does not denote any order, quantity, or importance, but rather is used to distinguish one element from another. Such terms as “include” or “comprise” means that the presence of an element or item preceding the word covers the presence of the element or item listed after the word and equivalents thereof, but does not exclude other elements or items. Such terms as “connected” or “connected” are not limited to physical or mechanical connections, but may include electrical connections, whether direct or indirect. Such terms as “upper”, “lower”, “left”, “right” are used only to indicate relative positional relationships that may change accordingly when the absolute position of the object being described changes.

It should be understood that when an element such as a layer, film, region, or substrate is referred to as being “on” or “under” another element, it can be “directly on” or “directly under” the other element or intervening elements may be present.

In the description of the embodiments above, particular features, structures, materials, or characteristics may be combined in any suitable manner in any one or more embodiments or examples.

The above embodiments are only specific embodiments of the present disclosure, but the protection scope of the present disclosure is not limited thereto. Anyone skilled in the art can easily think of changes or substitutions within the technical scope disclosed in the present disclosure, all of which shall fall within the protection scope of the present disclosure. Therefore, the protection scope of the present disclosure should be subjected to the protection scope of the claims.

1. A display panel, comprising: a display area and a peripheral area around the display area, wherein the display panel further comprises:
a plurality of sub-pixels in the display area;
a gate driving circuit comprising a plurality of shift register units, wherein the shift register units are coupled to the corresponding sub-pixels; and
a power signal transmission layer, wherein the power signal transmission layer comprises a portion in the display area and a portion in the peripheral area, and the shift register units are coupled to the power signal transmission layer.

2. The display panel according to claim 1, wherein the power signal transmission layer comprises a power bus section and a power compensation section;
the power bus section is in the peripheral area, is coupled to the shift register units and is further coupled to a power signal input terminal; and
the power compensation section is coupled to the power bus section, and at least a portion of the power compensation section is located in the display area.

3. The display panel according to claim 2, wherein the power compensation section comprises a plurality of first power compensation lines, each of the plurality of first power compensation lines is coupled to the power bus portion, and at least a portion of the first power compensation lines is in the display area.

4. The display panel according to claim 3, wherein the power compensation section comprises a plurality of second power compensation lines, an extension direction of the second power compensation line intersects with an extension direction of the first power compensation line, and the second power compensation lines are coupled to at least some of the first power compensation lines, respectively.

5. The display panel according to claim 4, wherein the first power compensation line and the second power compensation line are arranged on a same layer;
or,
wherein the first power compensation line and the second compensation line are arranged in different layers, and at least a portion of the first power compensation line is located between the second power compensation line and a base substrate of the display panel.

6. (canceled)

7. The display panel according to claim 3, wherein the sub-pixels comprise a plurality of sub-pixel driving circuits, and the plurality of sub-pixel driving circuits comprised in the plurality of sub-pixels are divided into a plurality of rows of sub-pixel driving circuits;
an orthographic projection of the first power compensation line onto a base substrate of the display panel overlaps at least partially with an orthographic projection of a corresponding row of sub-pixel driving circuits onto the base substrate; and
there are n rows of sub-pixel driving circuits between two rows of sub-pixel driving circuits corresponding to two adjacent first power compensation lines, wherein n is greater than or equal to 0.

8. The display panel according to claim 7, wherein the sub-pixel driving circuit comprises a driving transistor, a local refresh control transistor, and a second reset transistor, a gate electrode of the driving transistor is coupled to a second electrode of the local refresh control transistor, and a second electrode of the driving transistor is coupled to a second electrode of the second reset transistor;
the display panel further comprises a second initialization signal line and a local refresh control line, the second initialization signal line is coupled to a first electrode of the second reset transistor comprised in each of sub-pixel driving circuits in a corresponding row of sub-pixel driving circuits; and the local refresh control line is coupled to a gate electrode of the local refresh control transistor comprised in each of sub-pixel driving circuits in a corresponding row of sub-pixel driving circuits; and
at least a portion of the orthographic projection of the first power compensation line onto the base substrate is located between an orthographic projection of the second initialization signal line onto the base substrate and an orthographic projection of the local refresh control line onto the base substrate.

9. The display panel according to claim 7, further comprising data lines, wherein the data line is coupled to each of sub-pixel driving circuits in a corresponding column of sub-pixel driving circuits; or,
the display panel further comprises a plurality of first data lines and a plurality of second data lines, the first data line is coupled to each of odd-numbered sub-pixel driving circuits in a corresponding column of sub-pixel driving circuits, the second data line is coupled to each of even-numbered sub-pixel driving circuits in a corresponding column of sub-pixel driving circuits; an orthographic projection of the first data line onto the base substrate is located on a first side of an orthographic projection of the column of sub-pixel driving circuits coupled to the first data line onto the base substrate, an orthographic projection of the second data line onto the base substrate is located on a second side of an orthographic projection of the column of sub-pixel driving circuits coupled to the second data line onto the base substrate, and the second side is opposite to the first side.

10. The display panel according to claim 4, wherein the plurality of sub-pixel driving circuits comprised in the plurality of sub-pixels are divided into a plurality of columns of sub-pixel driving circuits; and
orthographic projections of m columns of sub-pixel driving circuits onto a base substrate are located between orthographic projections of two adjacent second power compensation lines onto the base substrate, wherein m is greater than or equal to 1.

11. The display panel according to claim 10, wherein the sub-pixel driving circuit comprises a driving transistor and a compensation transistor, and a second electrode of the driving transistor is coupled to a first electrode of the compensation transistor;
the display panel further comprises data lines, and the data line is coupled to each of sub-pixel driving circuits in a corresponding column of sub-pixel driving circuits; and
at least a portion of an orthographic projection of the second power compensation line onto the base substrate is located between an orthographic projection of an active layer of the compensation transistor onto the base substrate and an orthographic projection of a data line coupled to a sub-pixel driving circuit adjacent to the compensation transistor onto the base substrate;
or,
wherein the sub-pixel driving circuit comprises a driving transistor and a light emission control transistor, and a second electrode of the driving transistor is coupled to a first electrode of the light emission control transistor;
the display panel further comprises data lines, and the data line is coupled to each of sub-pixel driving circuits in a corresponding column of sub-pixel driving circuits; and
at least a portion of an orthographic projection of the second power compensation line onto the base substrate is located between an orthographic projection of an active layer of the light emission control transistor onto the base substrate and an orthographic projection of a data line coupled to a sub-pixel driving circuit adjacent to the compensation transistor onto the base substrate.

12. (canceled)

13. The display panel according to claim 10, further comprising a plurality of first data lines and a plurality of second data lines, wherein the first data line is coupled to each of odd-numbered sub-pixel driving circuits in a corresponding column of sub-pixel driving circuits, and the second data line is coupled to each of even-numbered sub-pixel driving circuits in a corresponding column of sub-pixel driving circuits;
an orthographic projection of the first data line onto the base substrate is located on a first side of an orthographic projection of the column of sub-pixel driving circuits coupled to the first data line onto the base substrate, an orthographic projection of the second data line onto the base substrate is located on a second side of an orthographic projection of the column of sub-pixel driving circuits coupled to the second data line onto the base substrate, and the second side is opposite to the first side; and
at least a portion of an orthographic projection of the second power compensation line onto the base substrate is located between orthographic projections of the first data line and the second data line that are adjacent to each other onto the base substrate.

14. The display panel according to claim 7, comprising a first power signal transmission layer and a second power signal transmission layer, wherein the first power compensation line comprised in the first power signal transmission layer and the first power compensation line comprised in the second power signal transmission layer are alternately arranged along a first direction.

15. The display panel according to claim 14, wherein an orthographic projection of the first power compensation line comprised in the first power signal transmission layer onto the base substrate overlaps at least partially with an orthographic projection of an odd-numbered row of sub-pixel driving circuits onto the base substrate, and an orthographic projection of the first power compensation line comprised in the second power signal transmission layer onto the base substrate overlaps at least partially with an orthographic projection of an even-numbered row of sub-pixel driving circuits onto the base substrate; or,
an orthographic projection of the first power compensation line comprised in the first power signal transmission layer onto the base substrate overlaps at least partially with an orthographic projection of an even-numbered row of sub-pixel driving circuits onto the base substrate, and an orthographic projection of the first power compensation line comprised in the second power signal transmission layer onto the base substrate overlaps at least partially with an orthographic projection of an odd-numbered row of sub-pixel driving circuits onto the base substrate;
or,
wherein the second power compensation line comprised in the first power signal transmission layer and the second power compensation line comprised in the second power signal transmission layer are alternately arranged along a second direction, and the second direction intersects with the first direction.

16. (canceled)

17. The display panel according to claim 15, wherein the sub-pixel driving circuit comprises a first reset transistor, and a second electrode of the first reset transistor is coupled to a gate electrode of the driving transistor;
the display panel further comprises a first initialization signal transmission layer structure, the first initialization signal transmission layer structure comprises a plurality of first initialization signal lines and a plurality of first initialization compensation lines; an extension direction of the first initialization compensation line intersects with an extension direction of the first initialization signal line; the first initialization signal line is coupled to a first electrode of the first reset transistor comprised in each of sub-pixel driving circuits in a corresponding row of sub-pixel driving circuits; and the first initialization compensation lines are coupled to at least some of the first initialization signal lines, respectively; and
an orthographic projection of the first initialization compensation line onto the base substrate and an orthographic projection of the second power compensation line comprised in the first power signal transmission layer onto the base substrate are alternately arranged along the second direction; and/or, an orthographic projection of the first initialization compensation line onto the base substrate and an orthographic projection of the second power compensation line comprised in the second power signal transmission layer onto the base substrate are alternately arranged along the second direction;
or,
wherein the sub-pixel driving circuit comprises a second reset transistor, and a second electrode of the second reset transistor is coupled to a second electrode of the driving transistor;
the display panel further comprises a second initialization signal transmission layer structure, and the second initialization signal transmission layer structure comprises a plurality of second initialization signal lines and a plurality of second initialization compensation lines, an extension direction of the second initialization compensation line intersects with an extension direction of the second initialization signal line; the second initialization signal line is coupled to a first electrode of the second reset transistor comprised in each of sub-pixel driving circuits in a corresponding row of sub-pixel driving circuits; and the second initialization compensation lines are coupled to at least some of the second initialization signal lines; and
an orthographic projection of the second initialization compensation line onto the base substrate and an orthographic projection of the second power compensation line comprised in the first power signal transmission layer onto the base substrate are alternately arranged along the second direction; and/or, an orthographic projection of the second initialization compensation line onto the base substrate and an orthographic projection of the second power compensation line comprised in the second power signal transmission layer onto the base substrate are alternately arranged along the second direction;
or,
wherein the sub-pixel driving circuit comprises a third reset transistor, and a second electrode of the third reset transistor is coupled with a first electrode of the driving transistor;
the display panel further comprises a third initialization signal transmission layer structure, the third initialization signal transmission layer structure comprises a plurality of third initialization signal lines and a plurality of third initialization compensation lines, an extension direction of the third initialization compensation line intersects with an extension direction of the third initialization signal line; the third initialization signal line is coupled to a first electrode of the third reset transistor comprised in each of sub-pixel driving circuits in a corresponding row of sub-pixel driving circuits; and the third initialization compensation line is coupled to at least some of the third initialization signal lines, respectively; and
an orthographic projection of the third initialization compensation line onto the base substrate and the orthographic projection of the second power compensation line comprised in the first power signal transmission layer onto the base substrate are alternately arranged along the second direction; and/or, an orthographic projection of the third initialization compensation line onto the base substrate and the orthographic projection of the second power compensation line comprised in the second power signal transmission layer onto the base substrate are alternately arranged along the second direction;
or,
wherein the sub-pixel driving circuit comprises a first reset transistor, a second reset transistor, and a third reset transistor; a second electrode of the first reset transistor is coupled to a gate electrode of the driving transistor, a second electrode of the second reset transistor is coupled to a second electrode of the driving transistor, and a second electrode of the third reset transistor is coupled to the first electrode of the driving transistor;
the display panel further comprises a first initialization signal transmission layer structure, a second initialization signal transmission layer structure, and a third initialization signal transmission layer structure;
the first initialization signal transmission layer structure comprises a plurality of first initialization signal lines and a plurality of first initialization compensation lines; an extension direction of the first initialization compensation line intersects with an extension direction of the first initialization signal line; the first initialization signal line is coupled to a first electrode of the first reset transistor comprised in each of sub-pixel driving circuits in a corresponding row of sub-pixel driving circuits; and the first initialization compensation lines are coupled to at least some of the first initialization signal lines, respectively;
the second initialization signal transmission layer structure comprises a plurality of second initialization signal lines and a plurality of second initialization compensation lines, an extension direction of the second initialization compensation line intersects with an extension direction of the second initialization signal line; the second initialization signal line is coupled to a first electrode of the second reset transistor comprised in each of sub-pixel driving circuits in a corresponding row of sub-pixel driving circuits; and the second initialization compensation lines are coupled to at least some of the second initialization signal lines, respectively;
the third initialization signal transmission layer structure comprises a plurality of third initialization signal lines and a plurality of third initialization compensation lines, an extension direction of the third initialization compensation line intersects with an extension direction of the third initialization signal line; the third initialization signal line is coupled to a first electrode of the third reset transistor comprised in each of sub-pixel driving circuits in a corresponding row of sub-pixel driving circuits; and the third initialization compensation lines are coupled to at least some of the third initialization signal lines, respectively;
the second initialization compensation line, the third initialization compensation line, and the first initialization compensation line are sequentially arranged in a cyclical manner along the second direction; the second initialization compensation line, the third initialization compensation line, and the first initialization compensation line are arranged in a same layer and made of a same material; and
the second power compensation line comprised in the first power signal transmission layer and the second power compensation line comprised in the second power signal transmission layer are arranged in a same layer and made of a same material, and are arranged in the layer different from the first initialization compensation line.

18. (canceled)

19. (canceled)

20. (canceled)

21. The display panel according to claim 17, wherein the display panel comprises a first source drain metal layer, a first source drain metal layer, and a third source drain metal layer stacked in sequence along a direction away from the base substrate;
the first power compensation line comprised in the first power signal transmission layer and the first power compensation line comprised in the second power signal transmission layer are both arranged in a same layer and made of a same material as the first source drain metal layer;
the second power compensation line comprised in the first power signal transmission layer and the second power compensation line comprised in the second power signal transmission layer are both arranged in a same layer and made of a same material as the second source drain metal layer; and
the second initialization compensation line, the third initialization compensation line, and the first initialization compensation line are all arranged in a same layer and made of a same material as the third source drain metal layer.

22. The display panel according to claim 15, wherein the sub-pixel driving circuit comprises a first reset transistor, a second reset transistor, and a third reset transistor; a second electrode of the first reset transistor is coupled to a gate electrode of the driving transistor, a second electrode of the second reset transistor is coupled to a second electrode of the driving transistor, and a second electrode of the third reset transistor is coupled to a first electrode of the driving transistor;
the display panel further comprises a first initialization signal transmission layer structure, a second initialization signal transmission layer structure, and a third initialization signal transmission layer structure;
the first initialization signal transmission layer structure comprises a plurality of first initialization signal lines and a plurality of first initialization compensation lines; an extension direction of the first initialization compensation line intersects with an extension direction of the first initialization signal line; the first initialization signal line is coupled to a first electrode of the first reset transistor comprised in each of sub-pixel driving circuits in a corresponding row of sub-pixel driving circuits; and the first initialization compensation line is coupled to at least some of the first initialization signal lines, respectively;
the second initialization signal transmission layer structure comprises a plurality of second initialization signal lines and a plurality of second initialization compensation lines, an extension direction of the second initialization compensation line intersects with an extension direction of the second initialization signal line; the second initialization signal line is coupled to a first electrode of the second reset transistor comprised in each of sub-pixel driving circuits in a corresponding row of sub-pixel driving circuits; and the second initialization compensation line is coupled to at least some of the second initialization signal lines, respectively;
the third initialization signal transmission layer structure comprises a plurality of third initialization signal lines and a plurality of third initialization compensation lines, an extension direction of the third initialization compensation line intersects with an extension direction of the third initialization signal line; the third initialization signal line is coupled to a first electrode of the third reset transistor comprised in each of sub-pixel driving circuits in a corresponding row of sub-pixel driving circuits; and the third initialization compensation line is coupled to at least some of the third initialization signal lines, respectively;
the plurality of first initialization compensation lines, the plurality of second initialization compensation lines, the plurality of third initialization compensation lines, the plurality of second compensation lines comprised in the first power signal transmission layer, and the plurality of second power compensation lines comprised in the second power signal transmission layer are divided into a plurality of first compensation groups, a plurality of second compensation groups, and a plurality of third compensation groups; the first compensation group, the second compensation group, and the third compensation group are sequentially arranged in a cyclical manner along the second direction;
the first compensation group comprises the second initialization compensation line, the first initialization compensation line, and the third initialization compensation line arranged in sequence;
the second compensation group comprises the second initialization compensation line, the first initialization compensation line, and the second power compensation line comprised in the first power signal transmission layer arranged in sequence; and
the third compensation group comprises the second initialization compensation line, the first initialization compensation line, and the second power compensation line comprised in the second power signal transmission layer arranged in sequence.

23. The display panel according to claim 22, wherein the display panel further comprises a first source drain metal layer, a second source drain metal layer, and a third source drain metal layer stacked in sequence along a direction away from the base substrate;
the first power compensation line comprised in the first power signal transmission layer and the first power compensation line comprised in the second power signal transmission layer are both arranged in a same layer and made of a same material as the first source drain metal layer; and
the second power compensation line comprised in the first power signal transmission layer, the second power compensation line comprised in the second power signal transmission layer, the second initialization compensation line, the third initialization compensation line, and the first initialization compensation line are all arranged in a same layer and made of a same material as the third source drain metal layer.

24. The display panel according to claim 2, wherein a line width d of the power bus section satisfies: 550 μm≤d≤150 μm;
or,
wherein the power bus section comprises a first bus layer, a second bus layer, and a third bus layer sequentially stacked along a direction away from a base substrate of the display panel. and the third bus layer is coupled to each of the first bus layer and the second bus layer.

25. (canceled)

26. The display panel according to claim 24, further comprising a first gate metal layer, a second gate metal layer, and a first source drain metal layer sequentially stacked in a direction away from the base substrate;
wherein the first bus layer is arranged in a same layer and made of a same material as the first gate metal layer, the second bus layer is arranged in a same layer and made of a same material as the second gate metal layer, and the third bus layer is arranged in a same layer and made of a same material as the first source drain metal layer.

27. A display device, comprising a display panel;
wherein the display panel comprises: a display area and a peripheral area around the display area, wherein the display panel further comprises:
a plurality of sub-pixels in the display area;
a gate driving circuit comprising a plurality of shift register units, wherein the shift register units are coupled to the corresponding sub-pixels; and
a power signal transmission layer, wherein the power signal transmission layer comprises a portion in the display area and a portion in the peripheral area, and the shift register units are coupled to the power signal transmission layer.
